(19) United States
(12) Patent Application Publication
(10) Pub. No.: US 2021/0351310 A1
(43) Pub. Date: Nov. 11, 2021

(54) SOLAR CELL VIA THIN FILM SOLDER BOND HAVING A STRAIN BALANCING LAYER

(71) Applicant: AmberWave, Inc., Lowell, MA (US)

(72) Inventor: Anthony Lochtefeld, Ipswich, MA (US)

(21) Appl. No.: 17/314,229

(22) Filed: May 7, 2021

Related U.S. Application Data
(60) Provisional application No. 63/021,865, filed on May 8, 2020.

(51) Int. Cl. H01L 31/0463; H01L 31/18

(52) U.S. Cl. CPC H01L 31/0463; H01L 31/186

(57) ABSTRACT

The present disclosure describes a solar cell that in one embodiment includes a substrate having a first thermal expansion coefficient; and a strain balancing layer on a surface of the substrate having a second thermal expansion greater than the first thermal expansion coefficient. The solar cell further includes a solder bonding layer on a surface of the strain balancing layer to position the strain balancing layer between the solder bonding layer and the supporting substrate. The solar cell further includes a semiconductor junction having a bonded surface on the solder bonding layer that is opposite the surface of the solder bonding layer engaged to the strain balancing layer.

### CROSS REFERENCE TO RELATED APPLICATION

The present invention claims the benefit of U.S. provisional patent application 63/021,865, filed May 8, 2020, the whole contents and disclosure of which is incorporated by reference as is fully set forth herein.

### TECHNICAL FIELD

The present disclosure relates to layer transfer, and more particularly relates to layer transfer of thin film material onto a substrate via solder bonding, in which planarity of the bonded stack is maintained through the incorporation of a strain balancing layer.

### BACKGROUND INFORMATION

Wafer bonding and splitting are methods for facilitating the transfer of thin film semiconductor materials used in making semiconductor substrates for solar cells, LEDs, LDs, optoelectronic integration circuits (OEIC) and microelectromechanical systems (MEMS).

### SUMMARY

The present disclosure provides methods and structures for providing solar cells that are resistant to warpage. Differences between the coefficient of thermal expansion (CTE) of a supporting substrate and the semiconductor material for the semiconductor junction of the solar cell can cause warpage in the device. In some examples, the supporting substrate may be composed of a steel based alloy, an iron nickel alloy, or a combination thereof. It has been determined that a strain balancing layer having a coefficient of thermal expansion (CTE) substantially greater than the coefficient of thermal expansion (CTE) of the supporting substrate positioned between the supporting substrate and the semiconductor material for the semiconductor junction of the solar cell can compensate for the difference in thermal expansion between these materials. The incorporation of the strain balancing layer provides a material stack that resists warpage, and hence provides a greater degree of planarity in solar cells when compared to similar material composition stacks that do not include the strain balancing layers that are described herein.

In one aspect, the present disclosure provides a solar cell device including a strain balancing layer. In one embodiment, the strain balancing layer is present directly on the supporting substrate.

In accordance with one embodiment, the solar cell includes a substrate having a first thermal expansion coefficient, which may be composed of a steel based alloy, an iron nickel alloy, or a combination thereof. The solar cell may further include a strain balancing layer on the surface of the supporting substrate. The strain balancing layer may have a second thermal expansion coefficient that is greater than the first thermal expansion coefficient of the supporting substrate. The solar cell further includes a solder bonding layer on a surface of the strain balancing layer to position the strain balancing layer between the solder bonding layer and the supporting substrate. In some embodiments, the solar cell includes a semiconductor junction having a bonded surface to the solder bonding layer that is opposite the surface of the solder bonding layer engaged to the strain balancing layer. The strain balancing layer counteracts a differential in the thermal coefficient of expansion between the semiconductor junction and the supporting substrate to counteract warpage.

In another aspect, the present disclosure provides a method for forming a solar cell device, in which the method employs a strain balancing layer for counteracting the effects of thermal expansion in semiconductor junction engaged to a supporting substrate by bonding techniques. The supporting substrate may have a composition that is selected from the group consisting of a steel based alloy, an iron nickel alloy and a combination thereof. In one embodiment, the method employs a strain balancing layer that is first formed on a supporting substrate. The layered stack of the supporting substrate and the strain balancing layer may then be joined to a semiconductor junction through a bonding method.

In one embodiment, the method may include forming a porous layer in a monocrystalline donor substrate; and forming an epitaxial semiconductor layer on the porous layer. The method may further include forming a semiconductor junction for the solar cell structure on the epitaxial semiconductor layer. In a following process step, a strain balancing layer is formed on a supporting substrate. A bonding layer engages the strain balancing layer that was formed on the supporting substrate to a stack including the semiconductor junction for the solar cell structure. Following the engagement of the bonding layer to the strain balancing layer for engaging the semiconductor junction to the supporting substrate, the semiconductor junction is separated from the monocrystalline donor substrate across the porous layer. The strain balancing layer counteracts a differential in the thermal coefficient of expansion between the semiconductor junction and the supporting substrate to counteract warpage.

In another embodiment, the strain balancing layer is present directly on the semiconductor junction, wherein the strain balancing layer is present between the semiconductor junction and solder bond layer. The solder bond layer joins the stack of the strain balancing layer and the semiconductor junction to a supporting substrate. In one embodiment, the solar cell includes a supporting substrate that has a first thermal expansion coefficient; a solder bonding layer on a surface of the supporting substrate; a strain balancing layer having a second thermal expansion greater than the first thermal expansion coefficient on a surface of the solder bonding layer opposite the surface of the solder bonding layer that is in contact with the supporting substrate; and a semiconductor junction engaged to the strain balancing layer. The supporting substrate may be composed of a steel based alloy, an iron nickel alloy, or a combination thereof.

In another aspect, the present disclosure provides a method for forming a solar cell device, in which the method employs a strain balancing layer that is formed on a semiconductor junction for countering warpage forces that result from differences in thermal expansion of different material compositions. In one embodiment, the method may include forming a porous layer in a monocrystalline donor substrate; and forming an epitaxial semiconductor layer on the porous layer. The method may further include forming a semiconductor junction for a solar cell structure on the epitaxial semiconductor layer. In a following process step, a strain balancing layer is formed on a material stack including the semiconductor junction for the solar cell structure. A bonding layer engages the strain balancing layer that was formed on the semiconductor junction for the solar cell structure to a supporting substrate. The supporting substrate may be composed of a steel based alloy, an iron nickel alloy, or a combination thereof. Following the engagement to the supporting substrate, the junction is separated from the monocrystalline donor substrate across the porous layer. The strain balancing layer counteracts a differential in the thermal coefficient of expansion between the semiconductor junction and the supporting substrate to counteract warpage of the stack of the semiconductor junction, bonding layer and the supporting substrate.

In yet another aspect, a method is provided for countering warpage effects in solar cell production by employing a bonding layer as a strain balancing layer. In one embodiment, the method includes forming a porous layer in a monocrystalline donor substrate; forming an epitaxial semiconductor layer on the porous layer; and forming a semiconductor junction for a solar cell structure on the epitaxial semiconductor layer. The junction for the solar cell structure is engaged to a supporting substrate through a bonding layer. The supporting substrate has a composition of a steel based alloy, an iron nickel alloy, or a combination thereof. The composition and thickness of the bonding layer is selected to provide a strain balancing layer. In a following step, the semiconductor junction is separated from the monocrystalline donor substrate across the porous layer, wherein the strain balancing layer provided by the bonding layer counteracts a differential in the thermal coefficient of expansion between the semiconductor junction and the supporting substrate to counteract warpage of the stack of the semiconductor junction, the bonding layer and the supporting substrate.

In another embodiment, a method of forming a solar cell device is provided that includes forming a strain balancing layer on a supporting substrate, the supporting substrate having a composition of a steel based alloy, an iron nickel alloy, or a combination thereof; and joining a crystalline semiconductor wafer to the supporting substrate, and the strain balancing layer to a layered stack including a semiconductor junction through a bonding layer. The method may further include thinning the crystalline semiconductor wafer with an etch back process; and forming a semiconductor junction with a crystalline semiconductor layer provided by the crystalline semiconductor wafer after said etch back process. In this method, the strain balancing layer counteracts a differential in the thermal coefficient of expansion between the semiconductor junction and the supporting substrate to counteract warpage of the stack of the semiconductor junction, the bonding layer and the supporting substrate.

### BRIEF DESCRIPTION OF THE DRAWINGS

These and other features and advantages of the present invention will be better understood by reading the following detailed description, taken together with the drawings wherein:

FIG. 1A is a side cross-sectional view illustrating warpage in a stack of different material layer that are adjacently stacked when the adjacent layers are composed of materials of different coefficients of thermal expansion.

FIG. 1B is a side cross-sectional view illustrating how a strain balancing layer can reduce warpage in a material stack composed of different material layers having different coefficients of thermal expansion.

FIGS. 2A-20 are side cross-sectional views of a forming a solar cell device with a strain balancing layer that has been formed on a supporting substrate for minimizing or substantially eliminating warpage, in accordance with an exemplary solder bonding embodiment of the invention.

FIG. 3 is a side cross-sectional view of a solar cell including a strain balancing layer for counteracting the effects of thermal expansion in semiconductor junctions engaged to supporting substrates by bonding techniques, in which the strain balancing layer is present directly on the supporting substrate, and a bonding layer is present between the strain balancing layer and the semiconductor junction, in accordance with one embodiment of the present disclosure.

FIGS. 4A-4D are side cross-sectional views of forming solar cell device with a strain balancing layer that has been formed on a material stack including the semiconductor junction of a solar cell for minimizing or substantially eliminating warpage, in accordance with an exemplary solder bonding embodiment of the invention.

FIG. 5 is a side cross-sectional view of a solar cell formed using a method that includes solder bonding, in which the solar cell includes a strain balancing layer that is present on a material stack including a semiconductor junction, wherein the strain balancing layer is present between the semiconductor junction and a solder bonding layer, in accordance with one embodiment of the present disclosure.

FIG. 6 is a side cross-sectional view of a solar cell formed using a method including a strain balancing layer, in which the solar cell being formed is a heterojunction silicon solar cell, in accordance with one embodiment of the present disclosure.

FIG. 7 is a flow chart for one embodiment of a method in accordance with the present disclosure.

### DETAILED DESCRIPTION OF THE PREFERRED EMBODIMENTS

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

The present disclosure provides methods and structures for providing solar cells that are resistant to warpage. Differences between the coefficient of thermal expansion (CTE) of a supporting substrate and the semiconductor material for the junction of the solar cell can cause warpage in the device. In some examples, the supporting substrate may be composed of a steel based alloy, an iron nickel alloy, or a combination thereof. It has been determined that a strain balancing layer having a coefficient of thermal expansion (CTE) substantially greater than the coefficient of thermal expansion (CTE) of the supporting substrate positioned between the supporting substrate and the semiconductor material for the junction of the solar cell can compensate for the difference in thermal expansion between these materials to provide a solar cell that is resistant to warpage. In some embodiments, the strain balancing layer has a coefficient of thermal expansion that is 50% greater than the supporting substrate.

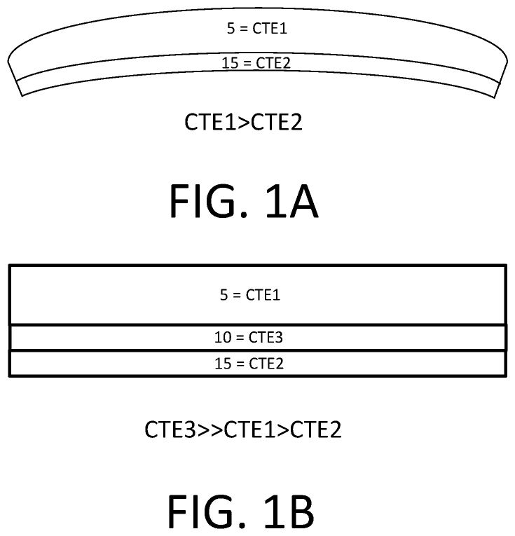

FIG. 1A depicts a solar cell without the strain balancing layer 10 that is described in the present disclosure. FIG 1A depicts one example of the type of warpage that can occur when the coefficient of thermal expansion (CTE) 1 of the supporting substrate 5 is greater than the coefficient of thermal expansion (CTE) 2 of the semiconductor junction 15 of the solar cell. FIG. 1B depicts how the incorporation of a strain balancing layer 10 having a coefficient of thermal expansion (CTE) 3 that is at least 50% greater than the coefficient of thermal expansion (CTE)1 for the supporting substrate 5 can counteract the original differential between the coefficient of thermal expansion (CTE) 1, 2 between the supporting substrate 5 and the semiconductor junction 15. In the example depicted in FIG. 1B, the strain balancing layer 10 is positioned between the supporting substrate 5 and the semiconductor junction 15, in which the greater thermal expansion of the strain balancing layer 10 when compared to the supporting substrate 5 and the semiconductor junction 15 mitigates the differential between these two material layers, i.e., the supporting substrate 5 and the semiconductor junction 15, so that the solar cell is resistant to warping and remains planar. The incorporation of the strain balancing layer 10 provides a material stack that resists warpage, and hence provides a greater degree in the planarity of solar cells when compared to similar material composition stacks that do not include the strain balancing layers described herein.

In some embodiments, the methods and structures described herein that employ strain balancing layers 10 are related to layer transfer and more particularly, relates to layer transfer of thin film material, such as thin film semiconductor materials used in ultra-thin monocrystalline solar cells, onto a substrate via solder bonding. Ultra-thin monocrystalline solar cells having a thickness of 100 microns or less. Ultra-thin monocrystalline solar cells can have several advantages over solar cells composed of multi-crystalline semiconductors or monocrystalline solar cells having a thickness greater than 100 microns.

Silicon material usage is substantially less than for standard monocrystalline silicon solar cells, especially for the case of thin silicon fabrication techniques that avoid the kerf loss (sawing loss) of approximately 150 microns per silicon wafer produced. This alone could reduce monocrystalline silicon solar cell costs significantly. Thin monocrystalline silicon solar cells offer the benefit of lower recombination volume, leading to higher open circuit voltages (Voc) and consequently higher cell efficiencies, leading to lower cost per watt. It has been determined that the aforementioned advantages by employing thin films to provide ultrathin monocrystalline solar cell can enable a new class of ultra-light, flexible, durable and high efficiency silicon photovoltaic (PV) module products for diverse markets, such as lightweight metal buildings, civilian and U.S. military portable power, and photovoltaic (PV) devices for developing countries with limited transportation infrastructure.

Despite the aforementioned benefits, it has been determined that free-standing silicon wafers below about 100 microns can be too fragile to be processed with low-cost automated cell processing techniques. Additionally, it has been determined that in some instances of photovoltaic designs employing thin semiconductor films that the solar cell efficiencies are disadvantageously low and can require non-standard and complicated cell processing techniques.

The following embodiments describe solar cell designs and fabrication processes which may be combined with the thin film solder bonding method. In some embodiments, the solder bonding method for forming photovoltaic devices including ultrathin monocrystalline solar cells can provide at least some of the aforementioned advantages.

Methods and structures for providing planar solar cells by employing a strain balancing layer 10 are now described in greater detail with reference to FIGS. 1A-5. It should be noted that although the various embodiments disclosed herein relate to a solar device, embodiments of the disclosure are not limited to solar devices and may be used in the construction of various microelectronic and optoelectronic devices.

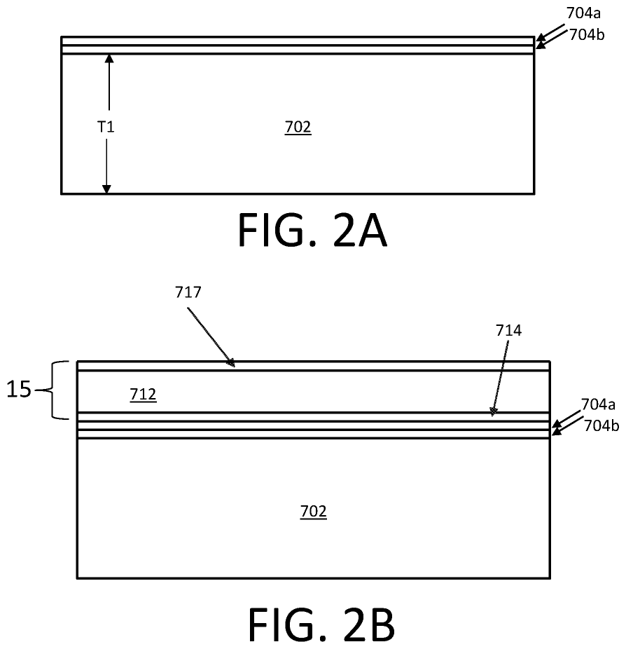

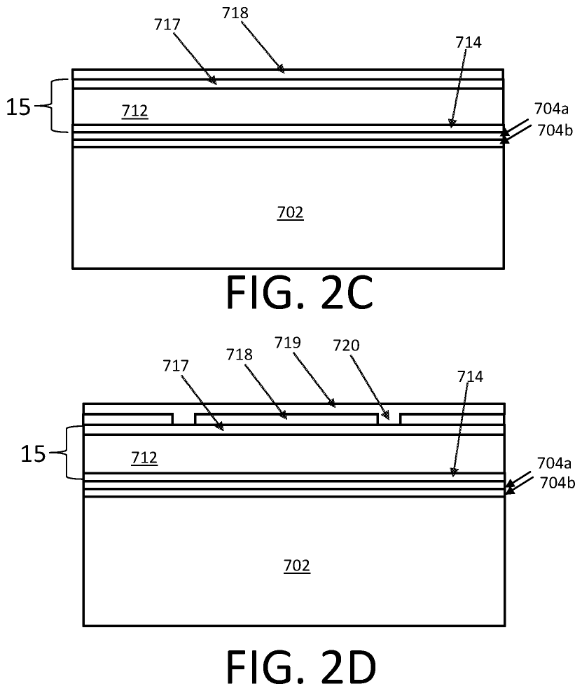

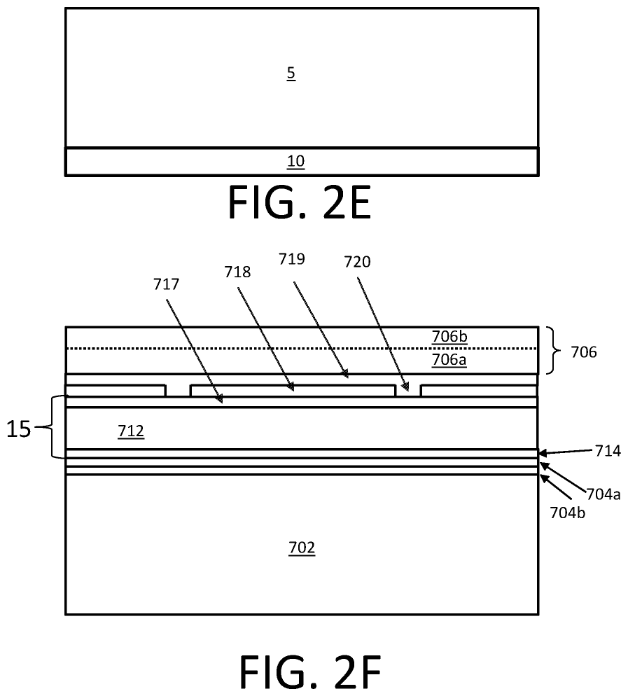

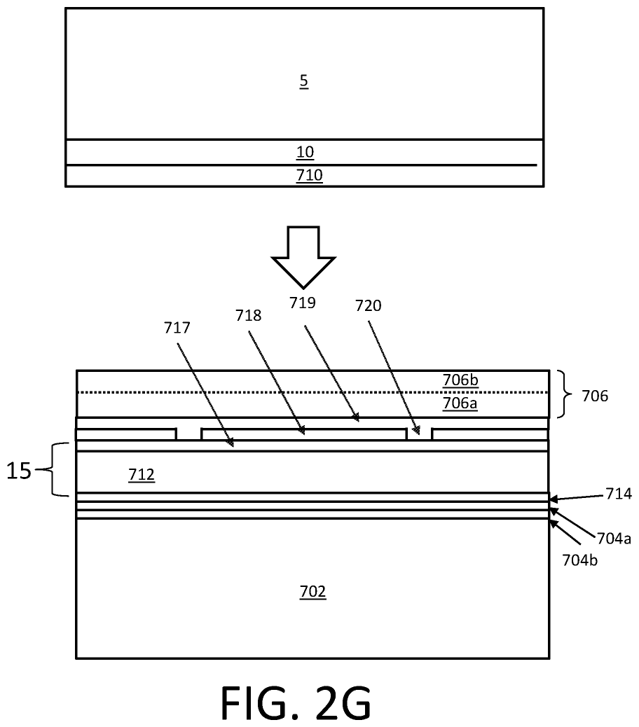

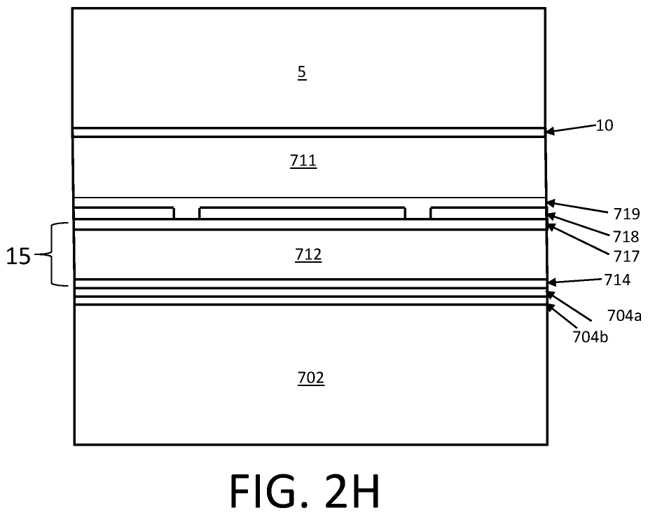

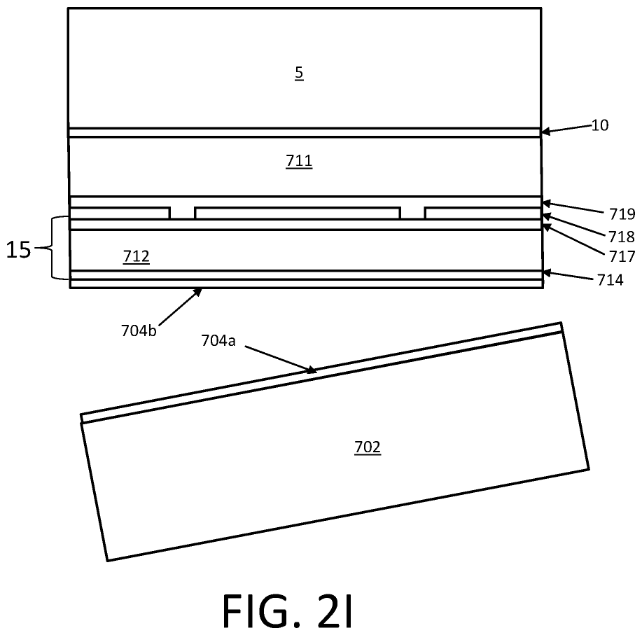

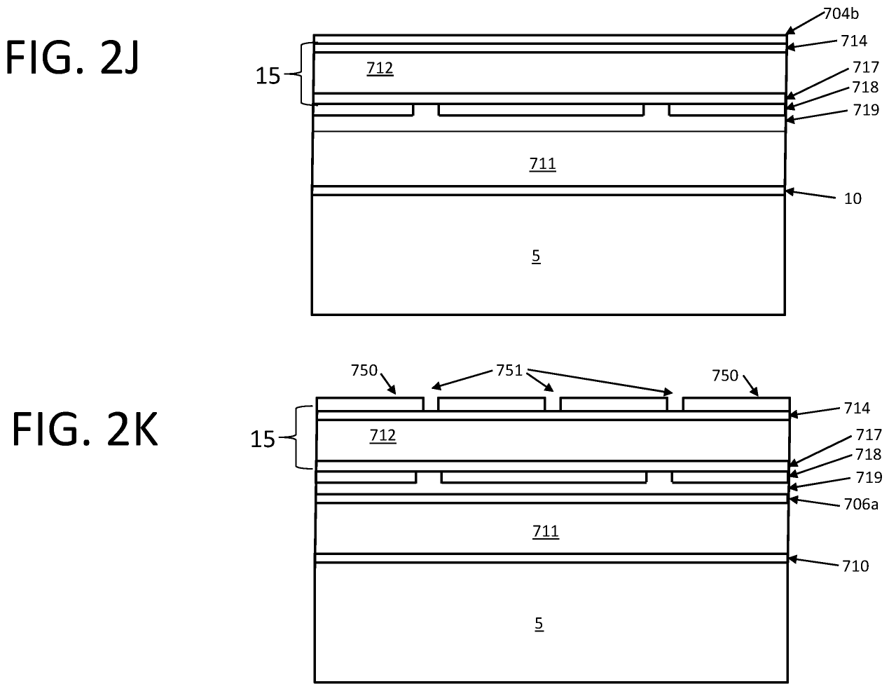

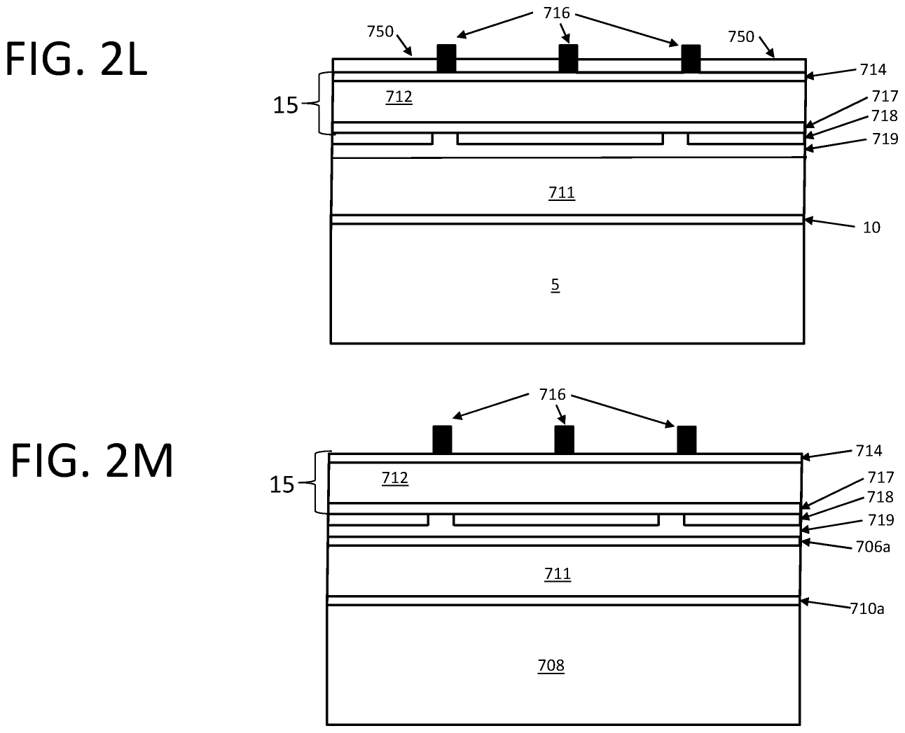

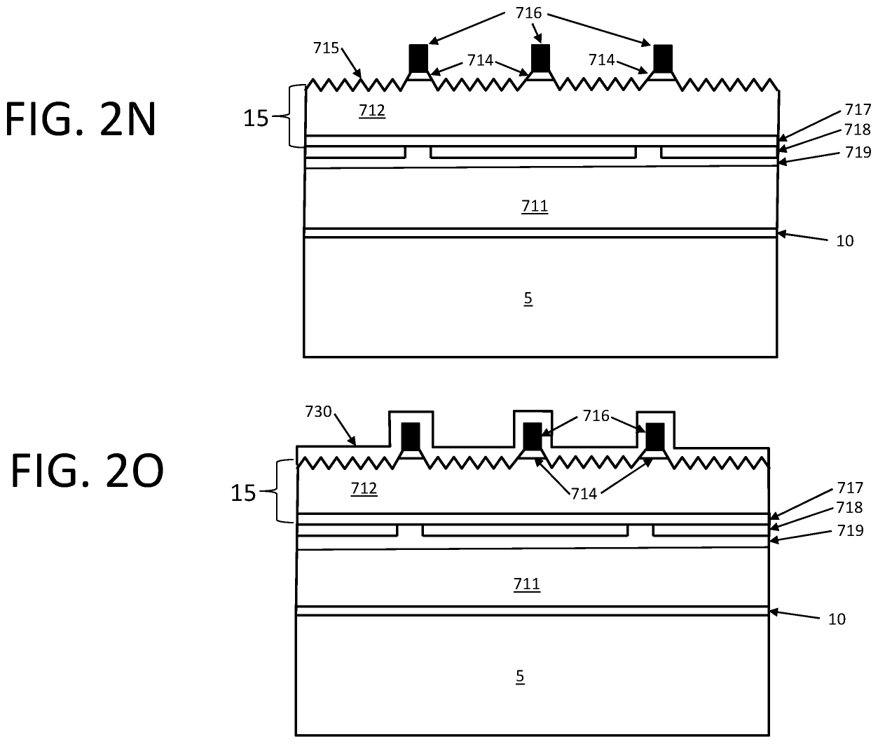

FIGS. 2A-2O depict one embodiment of a method for forming a solar cell including a strain balancing layer 10 for counteracting the effects of thermal expansion in semiconductor junctions 15 engaged to supporting substrates 5 by bonding techniques, in which the strain balancing layer 10 is present directly on the supporting substrate 5, and a bonding layer 706, 706a, 706b, 710, 711 is present between the strain balancing layer 10 and the semiconductor junction 15.

Referring to FIG. 2A, a monocrystalline donor substrate 702 may be used to construct a first portion of a solar cell and the porous region used later for separation. The monocrystalline donor substrate is composed of a type IV semiconductor. The term “type IV semiconductor material” denotes a semiconductor material that includes at least one element from Group IVA of the Periodic Table of Elements under the Old International Union of Pure and Applied Chemistry (IUPAC) classification system, or Group 14 of the New International Union of Pure and Applied Chemistry classification system. In some embodiments, the monocrystalline donor substrate 702 is a silicon (Si) substrate. It is noted that although the following example describes the use of a monocrystalline donor substrate 702 of monocrystalline silicon, embodiments have also been contemplated, in which other type IV semiconductor compositions may be employed, as well as type III-V semiconductor material compositions.

The donor substrate 702 may be, for example, but not limited to, a (100) or (111) surface orientation. In one example, the donor substrate 702 may have a thickness t1 of about 150 microns to 2000 microns. In another example, the donor substrate 702 may have a thickness ranging from 250 microns to 1000 microns. The diameter of the donor substrate 702 may be, but is not limited to, standard wafer sizes ranging from about 100 mm to 300 mm. In other embodiments, a square or semi-square substrate may be used, of approximately 5″ or 6″ on a side, such as is commonly used in crystalline Si solar cells. The donor substrate 702 may be doped p-type or n+ or alternately may be more lightly doped n-type if it is illuminated during porous silicon formation. As used herein, “p-type” refers to the addition of impurities to an intrinsic semiconductor that creates deficiencies of valence electrons. In a silicon donor substrate, examples of n-type dopants, i.e., impurities, include but are not limited to: boron, aluminum, gallium and indium. As used herein, “n-type” refers to the addition of impurities that contributes free electrons to an intrinsic semiconductor. In a silicon containing donor substrate 702, examples of n-type dopants, i.e., impurities, include but are not limited to antimony, arsenic and phosphorous. According to some embodiments, the donor substrate 702 may be p-type and have resistivity below about 1 ohm-cm.

Referring to FIG. 2A, in some embodiments, at least one porous layer, e.g., dual porous layers 704a, 704b, may be formed on the surface of the donor substrate 702. The top porous layer 704a may have a lower porosity, to serve as a template for subsequent epitaxial growth. The terms “epitaxial growth and/or deposition” means the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation. The bottom porous layer 704b may have a higher porosity, to allow subsequent splitting during layer transfer steps.

In one embodiment, the dual porous layers 704a, 704b are formed on the donor substrate 702 by a process that can include the step of immersing a p-type (100)-oriented monocrystalline Si substrate (also referred to as the donor substrate 702), which can have a resistivity ranging from, for example, 0.01 ohm-cm to 0.02 ohm-cm, in a solution composed of one part hydrofluoric (HF) acid, one part water (H₂PO), and one part isopropyl alcohol (C₃H₈O). The donor substrate 702 is arranged in the solution in series and in-line with two electrodes. The two electrodes may be formed of silicon or diamond. The two electrodes are arranged so that one of the electrodes is facing the front of the donor substrate 702 and the other of the two electrodes is facing the rear of the donor substrate 703. The substrate holder that supports the donor substrate 702 within the solution is electrically insulating, forcing electrical current to pass primarily through the donor substrate 702 and not around the wafer periphery. The electrodes may be separated from the donor substrate 702 by a distance of at least 10% of the diameter of the donor substrate 702. Through application of a voltage to such an apparatus, an electrical current flows in the solution and through the donor substrate 702, resulting in a porous silicon layer, e.g., dual porous layers 704a, 704b, being etched into a surface of the donor substrate 702.

Still referring to FIG. 2A, in some embodiments, two different voltages, one after another, may be applied between the electrodes while the donor substrate 702 is present in the suspension, resulting in the formation of two different porous silicon layers 704a, 704b on a surface of the donor substrate 702. In some embodiments, a first porous layer 704a can be formed on the surface of the donor substrate 702, which may be etched at a current density ranging from approximately 2 mA/cm² to 10 mA/cm². The first porous layer 704a may be etched into the donor substrate 702 to a depth of ranging from approximately 0.5 microns to 2 microns. The etch time for forming the first porous layer 04a may range from approximately 0.5 minutes to 5 minutes. The first porous layer 704a is a low porosity region, which can have a porosity ranging from 20% to 30%. In one example, the first porous layer 704a has a porosity of approximately 25%.

In some embodiments, a second porous layer 704b can be formed buried under the first porous layer 704a. The second porous layer 704b can be etched into the donor substrate 702 underlying the first porous layer 704a by applying a current density ranging from approximately 40 mA/cm² to approximately 200 mA/cm² to the donor substrate 702. The second porous layer 704b may be etched into the donor substrate 702 at a depth ranging from about 0.1 to about 1 microns. The etch time for forming the second porous layer 704b may range from approximately 2 seconds to approximately 30 seconds. The second porous layer 704b may have a higher porosity than the first porous layer 704a.

In some embodiments, after etching, the wafers may be rinsed in deionized water, and dried for example under a heated nitrogen flow. In some embodiments, the second porous layer 704b defines a cleave plane after subsequent cleaning, epitaxy, and bonding process steps.

Further details for one exemplary approach to creating a splitting plane, e.g., creating the first and second porous layers 704a, 704b, is described in, for example, Yonehara & Sakaguchi, JSAP Int. July 2001, No. 4, pp. 10-16. The porous layers 704 may also be stabilized via brief thermal oxidation and may also be sealed via anneal under H₂ as also described in Yonehara & Sakaguchi, JSAP Int. July 2001, No. 4, pp. 10-16.

In some embodiments, the surface of the porous silicon layers 704a may be heated to form an essentially continuous single crystal silicon layer, via anneal under hydrogen (H₂) gas. This step may be conducted in a silicon growth system, or optionally, in a separate annealing system prior to locating the wafers into the silicon growth system. In one example, the Si donor substrate 702 may be subjected to a flow of hydrogen (H₂) at a flow rate ranging from 1 sccm to 100 sccm (standard cubic centimeters per minute) at a temperature of about 900° C. to 1150° C. for a time period ranging from 5 minutes to 60 minutes.

Referring to FIG. 2B, in some embodiments, the method may continue with forming an epitaxial semiconductor layer 714 on the first porous layer 704a that is formed on the donor substrate 702. In some embodiments, the epitaxial semiconductor layer 714 may be an n-type doped epitaxial silicon (Si) film. The epitaxial semiconductor layer 714 may have a thickness ranging from approximately 100 nm to 1000 nm.

In one example, forming the epitaxial semiconductor layer 714 can begin with loading the donor substrate 702 in a silicon (Si) growth system. In some examples, the epitaxial semiconductor layer 714 may be grown on top of the porous region using Atmospheric Pressure Chemical Vapor Deposition (APCVD) or Low Pressure Chemical Vapor Deposition (LPCVD), for example, with precursors such as dichloro-silane (DCS) or trichloro-silane (TCS), at temperatures above e.g. 700C. The epitaxial semiconductor layer 714 may be formed using an epitaxial deposition process including in situ doping to provide the conductivity type of the epitaxial semiconductor layer 714. The term “in situ” denotes that a dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gasses.

Still referring to FIG. 2B, in one example, the epitaxial semiconductor layer 714 may be an n-type doped epitaxial silicon film with in-situ doping via e.g. phosphorus to a level of greater than about 5×10¹⁷ cm⁻³, for example greater 10¹⁹ cm⁻³. The epitaxy can be performed for example in a batch reactor system to enable lower cost; e.g., an ASM A412 Batch CVD Furnace (see for example “SiGe Epitaxy on A 300 Mm Batch Furnace”, Andreas Naumann et al, J Nanosci Nanotechnology. 2011 September; 11(9): 8040-3).

A typical precursor used for n-type in-situ doping is phosphine. This n-type region 714 may serve as the base contact region of the solar cell. In some embodiments, high quality epitaxial regions are formed on porous silicon, and may involve a step before epitaxial growth to seal the exposed surface pores, such as, for example, an anneal step under an H₂ ambient. In one example, an anneal process for sealing the exposed surface pores is described e.g. in N. Sato at S. Ishii et al, “Reduction of Crystalline defects to 50/cm² in Epitaxial Layers of Porous Silicon for ELTRAN® Process”, in the proceedings of the 1998 IEEE Silicon on Insulator conference.

Still referring to FIG. 2B, in a following step, an n-type doped epitaxial film 712 of thickness e.g. 3-50 microns, with in-situ doping via e.g. arsenic or phosphorous to a level of e.g. 1×10¹⁵ cm⁻³-5×10¹⁷ cm⁻³ may then be grown to provide the base (absorber) region of the solar cell. The n-type doped epitaxial film 712 may also be referred to as base region layer 712. The base region 712 and the subsequently formed emitter region 717 provide the semiconductor junction 15 of the solar cell. In some embodiments, the base region layer 712 is composed of silicon (Si). However, embodiments have also been contemplated, in which the base region layer 712 is composed of another type IV semiconductor material, or a type III-V semiconductor material.

The semiconductor material layer that ultimately provides the emitter region layer 717 of the solar cell is then formed on the base region layer 712. In some embodiments, the emitter region layer 717 is composed of a semiconductor material that has an opposite conductivity type as the base region layer 712. The interface of the base region layer 712, and the emitter region layer 717 form a p-n junction, and the interaction of these two layers may be referred to as junction layers. For example, when the base region layer 712 is composed of n-type silicon, the emitter region layer 717 may be composed of a p-type semiconductor material, such as p-type silicon. For example, the emitter region layer 717 may be epitaxially formed in situ doped p-type semiconductor material that is growth to a thickness ranging from 100 nm to 5000 nm. To provide the p-type conductivity, the emitter region layer 717 may be in-situ doped, e.g., in situ doped with boron, to a level of greater than about 10¹⁷ cm⁻³. Similar to the base region layer 712, the emitter region layer 717 may be composed of other type IV semiconductor materials besides silicon, and may also be composed of type III-V semiconductor materials.

Referring to FIG. 2C, a rear surface passivation layer may be formed on the structure depicted in FIG. 2B. In one embodiment, a passivation layer 718 is disposed upon the surface of emitter region layer 717, which can be a p-type silicon layer. The passivation layer 718 may be used to passivate silicon solar cells, and may have a composition such as amorphous silicon (α-Si), silicon nitride (SiNₓ), silicon dioxide (SiO₂), silicon oxy-nitride (SiONₓ), aluminum oxide (Al₂O₃), or a combination of these layers, such as Al₂O₃ followed by either SiNₓ, SiONₓ, or SiO₂.

In some embodiments, the passivation layer 718 may be deposited via common methods, well known in the art, such as plasma-enhanced chemical vapor deposition (PECVD), atomic layer deposition (ALD), or in the case of SiO₂, wet chemical oxidation or thermal oxidation of the emitter region layer 717 when composed of s silicon containing material, such as p-type silicon. The thickness of the passivation layer 718 or layers can be in the range of e.g. 10 nm to 500 nm. In one example, the passivation layer 718 can be provided by a first dielectric material, such as aluminum oxide layer of thickness in the range of 5 nm to 50 nm, which can be capped by a second dielectric material layer of SiNₓ, SiONₓ, or SiO₂ having a thickness in the range of 50 nm to 300 nm.

Referring to FIG. 2D, a contact layer 719 may be disposed on passivation layer 718. In some embodiments, the contact layer may comprise a metal composition, such as aluminum (Al), and may be deposited via standard methods such as evaporation, sputtering, screen printing (of aluminum-containing paste), plating or a combination thereof.

In cases where passivation layer 718 is electrically insulating, contact layer 719 will need to penetrate a portion of passivation layer 718 to achieve electrical contact to the solar cell, via openings 720. Referring to FIG. 1D, the portion of the contact layer 719 that extends through the openings 720 through the passivation layer 718 are in direct contact with the emitter region layer 717. The openings 720 can be formed by methods, including photolithography, laser annealing, laser ablation and combinations thereof. The process sequence for forming the openings 720 through the passivation layer 718 are typically performed before forming the contact layer 719. One example of forming openings 720 through a passivation layer 718 is described in Jens Muller et al, Journal of Applied Physics 108, 124513 (2010)).

In another embodiment, the contact layer 719 may be formed including portions that are fired through the passivation layer 718 into contact with the emitter region layer 717. One example of a method for firing the contact layer 719 through the passivation layer 718 is described in, for example, E. Schneiderlochner, R. Preu, R. Lüdemann, and S. W. Glunz, “Laser-Fired Rear Contacts for Crystalline Silicon Solar Cells,” Progress in Photovoltaics: Research and Applications 20 (2002) 29.

Note that the combination of a dielectric layer (passivation layer 718) backed by a metal layer (contact layer 719), such as aluminum, can form a very effective reflector layer for the rear of the completed solar cell. Further details for one example of employing the combination of the dielectric layer (passivation layer 718) backed by a metal layer (contact layer 719) can be found in “Hybrid Dielectric-Metallic Back Reflector for Amorphous Silicon Solar Cells” by Mutitu et al. in Energies 2010, 3, 1914-1933.

In the methods for forming openings 720 that includes photolithography, laser ablation and/or laser annealing, after contact layer 719 deposition, an anneal may be performed to cause Al doping of the Si through the openings 720 (such as described in “Characterization Of Local Al-BSF Formation For Perc Solar Cell Structures” by Grasso et al, Proceedings of the 25th European PV Solar Energy Conference, Valencia, Spain, 2010) thus forming p+ regions in the silicon (not illustrated) aligned with the contact openings 720. In some embodiments, these p+ regions may be doped up to about 10¹⁹ cm⁻² or higher, and may extend into silicon up to e.g. 1-10 microns. This can lead to reduced contact resistance in the solar cell.

Referring to FIGS. 2E and 2F, in one embodiment, the method may continue with the formation of a bonding layer 706, 706a, 706b, and the employment of the bonding layer 706, 706a, 706b to connect a stacked structure of a strain balancing layer 10 and a supporting substrate 5.

FIG. 2E illustrates forming the strain balancing layer 10 on the supporting substrate 5. The supporting substrate 5 may be composed of a metal, such as steel, or a low coefficient of thermal expansion (low-CTE) iron-nickel alloy. For example, the supporting substrate 5 may be selected to have a coefficient of thermal expansion (C.TE) of 15 ppm/° K. or less. In another example, the coefficient of thermal expansion (C.TE) for the supporting substrate 5 may be equal to 10 ppm/° K. or less.

In one embodiment, the supporting substrate 5 is composed of stainless steel. Stainless steel is a steel alloy with a minimum of 11% chromium (Cr) content by mass and a maximum of 1.2% carbon (C) by mass. In one embodiments, the supporting substrate 5 may be composed of stainless steel that is grade 410 (UNS S41000). In some embodiments, grade 410 stainless steel that provides the supporting substrate 5 has the composition that includes a majority of iron (Fe), <0.15% carbon (C), 11.5%-13.5% chromium (Cr), >0.75% nickel (Ni), <1.0% manganese (Mn), <1.0% silicon (Si), <0.04% phosphorus (P), and <0.03% sulfur (S).

In some embodiments, low-CTE metals of an iron nickel alloy that is suitable for the supporting substrate 5 can include Kovar™ or Invar™. For example, the iron nickel alloy may include between 25% to 40% nickel (Ni), up to 20% cobalt (Co), silicon (Si) at less than 1%, chromium (Cr) less than 0.5%, carbon (C) at less than 0.5%, and a majority of iron (Fe). In one example, when the supporting substrate 5 is composed of Kovar™the composition of the supporting substrate 5 may include nickel (Ni) 29% (e.g., up to 29%), cobalt (Co) 17%, silicon (Si) 0.2%, chromium (Cr) 0.2%, and a remainder of iron (Fe). In one example, when the supporting substrate 5 is composed of Invar™, the composition of the supporting substrate 5 may include 35% to 38% nickel (Ni), up to 1% cobalt (Co), up to 0.025% silicon (Si), up to 0.50% chromium (Cr), up to 0.06% manganese (Mn), up to 0.10% carbon (C), up to 0.025% phosphorus (P), up to 0.025% sulfur (S), up to 0.50 cobalt (Co), and a remainder of iron (Fe).

In some embodiments, the supporting substrate 5 may be of the same, or a similar size, as the donor substrate 702, or it may be larger, such as to support multiple solar cells. In one embodiment, the supporting substrate 5 may be rigid with a thickness in the range of 20 microns to 200 microns. In other embodiments, the supporting substrate 5 may have a thickness ranging from 50 microns to 100 microns.

In some examples, the strain balancing layer (SBL) 10 is formed directly on the surface of the supporting substrate 5 that provides the bonding interface with the layered stack including the semiconductor junction that is depicted in FIG. 2D. The composition of the strain balancing layer (SBL) 10 is selected to have a coefficient of thermal expansion (CTE) that is at least 50% higher than the coefficient of thermal expansion (CTE) for the supporting substrate 5. In some embodiments, the strain balancing layer (SBL) 10 is selected to have a coefficient of thermal expansion (CTE) that ranges from 100% to 200% greater than the coefficient of thermal expansion (CTE) for the supporting substrate 5.

The composition of the strain balancing layer (SBL) 10 may have a composition selected from the group consisting of zinc (Zn), aluminum (Al), copper (Cu), indium (In) and combinations thereof. In some embodiments, the strain balancing layer (SBL) 10 may be entirely composed of zinc (Zn), e.g., the strain balancing layer (SBL) 10 is 100% zinc (Zn). In one embodiment, the strain balancing layer (SBL) 10 is formed only on one side of the supporting substrate 5, e.g., the side of the supporting substrate 5 that is closest to bonding with the semiconductor junction 10. The strain balancing layer (SBL) 10 may have a thickness as great as 20 microns.

It is noted, that the composition of the strain balancing layer (SBL) 10, the thickness of the strain balancing layer (SBL) 10, the composition of the supporting substrate 5, the thickness of the supporting substrate 5, and the positioning of the strain balancing layer (SBL) 10 relative to the supporting substrate 5 are all considered in selecting the characteristics of the strain balancing layer (SBL) 10 for providing solar cells that are resistant to warpage. For example, strain energy in the strain balancing layer (SBL) 10 can be calculated using the following equation:

U=(½) V E ε² EQUATION 1:
U: strain energy
V: Film volume
E: Young's modulus
249 : Film strain
α: Coefficient of Linear Thermal Expansion
ΔT: Difference between bonding T and room T
t: film thickness

In the embodiments, in which the strain balancing layer 10 is positioned between a semiconductor junction layer 15, such as a silicon semiconductor junction, and a steel alloy based supporting substrate 5, the equation can be written as in equations 2 and 3:

Uₛᵢ=(½) Vₛᵢ Eₛᵢ ε_{Si}² EQUATION 2:

U_{SBL}=(½) V_{SBL} E_{SBL} ε_{SBL}² EQUATION 3:

The wafer structure is bonded at elevated temperature. Because the different layers have different Coefficients of Linear Thermal Expansion (α), after bonding upon cooling the different layers shrink at different rates, e.g., the supporting substrate 5, the strain balancing layer 10 and the semiconductor junction layer 15, leading to wafer bowing at room temperature (T)(e.g., 20° C. to 25° C.). This has been illustrated above with reference to FIG. 1A. In order to minimize bowing of the supporting substrate 5, e.g., supporting substrate 5 comprised of a steel alloy, we want the strain energy in the strain balancing layer (SBL) to be equal in magnitude but opposite in sign to the strain energy in the supporting substrate 5. This is the condition for strain balance.

If the steel substrate is substantially thicker than either the strain balancing layer (SBL) or the semiconductor junction layer 15 (also referred to as Si film) (for example, at least 5× as thick as either of those layers), we can assume that the strain in the semiconductor junction layer 15 (also referred to as Si film) and the strain balancing layer (SBL) are as follows, in Equations 4 and 5:

ε_{Si}≈ΔT(α_{Si}-αₛₜₑₑₗ) EQUATION 4:

ε_{SBL}≈ΔT(α_{SBL}-αₛₜₑₑₗ) EQUATION 5:

Combining equations 4 and 5, the condition for strain balance can be expressed in equation 6, as follows:

V_{Si} E_{Si} (α_{Si}-αₛₜₑₑₗ)²≈t_{SBL} E_{SBL} (α_{SBL}-αₛₜₑₑₗ)² [where α_{SBL}>αₛₜₑₑₗ>α_{Si}] EQUATION 6:

Equation 7 illustrates assuming that the films, i.e., the strain balancing layer cover equal areas, this becomes:

t_{Si} E_{Si} (α_{Si}-αₛₜₑₑₗ)²≈t_{SBL} E_{SBL} (α_{SBL}-αₛₜₑₑₗ)²

Equation 7 solving for the thickness of the strain balancing layer (t_{SBL}) is expressed in equation 8, as follows:

$${t}_{S B L} \approx \frac{{t}_{S i} {{E}_{S i} ( {α}_{S i} - {α}_{steel} )}^{2}}{{{E}_{S B L} ( {α}_{S B L} - {α}_{steel} )}^{2}} \\ [ where {α}_{S B L} > {α}_{steel} > {α}_{S i} ] \qquad EQUATION 8$$

Equation 8 defines the thickness of the strain balancing layer (SBL) 10 to satisfy the strain balance condition. By satisfying the strain balance condition it is meant that the composition and thickness of the strain balancing layer (SBL) 10 is selected to counteract the forces that result from the differential in the coefficient of thermal expansion (CTE) between the supporting substrate 5 and the semiconductor junction 15 to provide a planar stack for a solar cell as depicted in FIG. 1B. Referring to FIGs. 1A and 1B, satisfying the strain balance condition can avoid solar cell warpage, as depicted in FIG. 1A, and provide a planar solar cell, as depicted in FIG. 1B.

Referring back to FIG. 2E, the strain balancing layer (SBL) 10 is formed using electroplating, physical vapor deposition (PVD), sputtering, evaporation, electroless deposition and combinations thereof. Electroplating is a process that uses electrical current to control the flow of charged particles, such as metal cations and anions, so that they form a coherent metal coating, e.g., strain balancing layer 10, on an electrode, which may provide the deposition surface of the supporting substrate 5. As used herein, “sputtering” means a method of depositing a film of material, i.e., strain balancing layer (SBL) 10 on a deposition surface, e.g., supporting substrate, in which a target of the desired material, i.e., source, is bombarded with particles, e.g., ions, which knock atoms from the target, and the dislodged target material deposits on the deposition surface. Examples of sputtering techniques suitable for depositing the strain balancing layer (SBL) 10 include, but are not limited to, DC diode sputtering (“also referred to as DC sputtering”), radio frequency (RF) sputtering, magnetron sputtering, and ionized metal plasma (IMP) sputtering.

In other embodiments, e.g., when the strain balancing layer (SBL) 10 is composed of zinc (Zn), the strain balancing layer (SBL) 10 may be formed using hot dipping, which may also be referred to as hot-dip galvanization. Hot-dip galvanization is a form of galvanization. It is the process of coating iron and steel with zinc, which alloys with the surface of the base metal when immersing the metal in a bath of molten zinc at a temperature of around 449° C. (840° F.).

It is noted that in some embodiments, the strain balancing layer (SBL) 10 is only present on one side of the supporting substrate 5. The strain balancing layer (SBL) 10 is not present on the opposing side of the supporting substrate 5 from which the strain balancing layer (SBL) 10 is deposited onto. In some embodiments, the strain balancing layer (SBL) 10 is positioned on one side of the supporting substrate 5 to provide that the strain balancing layer (SBL) 10 is positioned between the supporting substrate 5 and the semiconductor junction 15 in the final solar cell structure. In some embodiments, if material is formed on the backside surface (i.e., the surface of the supporting substrate 5 opposite the deposition surface that interfaces with the stack including the semiconductor junction during bonding) of the supporting substrate 5, it may be removed by planarization, grinding, chemical mechanical planarization (CMP), etching etc.

Referring to FIG. 2F, the process flow can continue by forming conductive metal bonding layers 706a, 706b on the surface of the contact layer 719 that is connected to the donor substrate 702. In one embodiment, bonding layers 706a, 706b may be comprised of a high melting point metal layer 706a followed by a low-melting-point metal layer 706b. Each of the high melting point layer 706a, and the low melting point layer 706b, may have a thickness ranging from about 0.5 microns to about 5.0 microns. It is noted that the combination of high melting point and low melting point metal layers 706a, 706b may be advantageous for forming transient liquid phase bond in bonding methods that want this type of bonding. However, the present method is not limited to only this example, as any solder bonding method may be employed. The term “solder”, as used herein, refers to any metal or metallic compound or alloy that is melted and then allowed to cool and solidify in order to join two or more metallic surfaces together. Generally speaking, solders have melting temperatures in the range of 150° C. to 250° C. In some embodiments, the solder can be made from lead-free solder mixtures or lead tin solder.

Referring back to the embodiment depicted in FIG. 2F, the high melting point layer 706a could be composed of nickel (Ni) or titanium (Ti), and the low melting point layer 706b may be tin (Sn). In another example, the high melting point layer 706a could be copper (Cu), and the low melting point layer 706b may be indium (In). In some embodiments, the high melting point layer 706a may be of thickness sufficient so that all of low melting point layer 706b is consumed in the formation of an intermetallic compound layer as is described subsequently. In one example, the high melting point layer 706a may be 50% thicker than the low melting point layer 706b. Additionally, in some examples, the deposition of the high melting point layer 706a may be preceded by deposition of a thin layer to promote adhesion. In some examples, the thin layer for promoting adhesion can be composed of a metal, such as chromium (Cr) or titanium (Ti), and can have a thickness ranging from 5 nm to 50 nm.

The high melting point layer 706a and the low melting point layer 706b that provide the bonding layers, as well as the thin layer for promoting adhesion, may be deposited by processes that can include, but are not limited to, thermal evaporation, sputtering, electrodeposition, electroless plating, or screen printing. The deposition process may be performed such that there is no exposure to an oxygen-containing ambient between the depositions of different metal layers, to prevent native oxide formation between the different metal layers.

Referring to FIG. 2G, in some embodiments, the supporting substrate 5 having the strain balancing layer (SBL) 10 present thereon may be prepared for bonding to the donor substrate 702, including the semiconductor junction 15 of a solar cell. The bonding between the donor substrate 702 and the supporting substrate 5 can be provided through the high melting point layer 706a and the low melting point layer 706b that provide the bonding layers between the donor substrate 702 and the supporting substrate 5. However, in some embodiments, additional bonding layers may be formed on the strain balancing layer (SBL) 10 prior to bonding. It is noted that the additional metal bonding layers 710 are optional and may be omitted.

In some embodiments, the metal bonding layers 710 may be deposited on the surface of the strain balancing layer (SBL) 10. In one embodiment, the metal bonding layers 710 may be comprised of a high melting point metal layer followed by a low-melting-point metal layer. It is noted that the bilayer of the high melting point metal layer/low-melting-point metal layer is helpful for forming intermetallic compound layer in the bonding layer 711 (as depicted in FIG. 2H) that engages the stack including the supporting substrate 5 and the strain balancing layer 10 to the stack including the semiconductor junction 15. However, as noted above, any bonding composition may be employed in the bonding layer 711, and it is not necessary that the bonding composition form an intermetallic compound layer.

However, in the embodiments that do form a bonding layer 711 having an intermetallic compound, each of the high melting point layer, and the low melting point layer, may have a thickness ranging from about 0.5 microns to about 5.0 microns. In one example, the high melting point layer may be composed of nickel (Ni) or titanium (Ti), and the low melting point layer may be composed of tin (Sn). In another example, the high melting point layer may be composed of copper (Cu), and the low melting point layer may be composed of indium (In). It is noted that the high melting point layer may be of thickness sufficient so that all of low melting point layer is consumed in the formation of intermetallic compound layer for the bonding layer 711, as described subsequently. For example, the high melting point layer may be 50% thicker than the low melting point layer. In some embodiments, deposition of high melting point layer may be preceded by deposition of a thin layer to promote adhesion, such as chromium (Cr) or titanium (Ti). The adhesion promoting layer may have a thickness ranging from 5 nm to 50 nm.

The high melting point layer and the low melting point layer that provides the metal bonding layer 710 (depicted in FIG. 2I), as well as the adhesion promoting layer, may each be deposited by thermal evaporation, sputtering, electrodeposition, electroless plating, screen printing or a combination thereof. The deposition may be performed such that there is no exposure to an oxygen-containing ambient between the depositions of different metal layers, to prevent native oxide formation between the different metal layers. In one embodiment, the low temperature metal bonding layer that is described with reference to FIG. 2G may be of the same material as the low temperature bonding layer identified by reference number 706b that is described with reference to FIG. 2F. In one embodiment, the high temperature metal bonding layer that is described with reference to FIG. 2G may be of the same material as the high temperature bonding layer identified by reference number 706a that is described with reference to FIG. 2F. For example, each of the low temperature metal bonding layers may both be comprised of tin (Sn); and each of the high temperature metal bonding layers may both be comprised of nickel (Ni) or titanium (Ti).

Referring to FIG. 2G, prior to bonding any native metal oxides that may have formed on the exposed surface of the metal bonding layers may be removed via a plasma cleaning step. In one example, the plasma cleaning step may employ an AQ-2000 plasma cleaner made by Samco. Removal of the oxides is not required, but can improve the quality of the bond that engages the donor substrate 702 to the support substrate 5.

In some embodiments, the wafer bonding, i.e., bonding between the donor substrate 702 and the support substrate 5, can be achieved in a tool, such as an EVG (Electronic Visions Group) 510 bonder, or a SUSS SB6e bonder, or a heated mechanical press, or in a solar module laminator, possibly modified for higher laminating temperature. In one embodiment, the donor substrate 702 and support substrate 5 are approximately the same size, and are brought substantially into alignment prior to contact, e.g. with not more than 1 mm lateral offset, within the bonding tool. In one example, the wafers, e.g., the donor substrate 702 and the support substrate 5, may be brought into contact in a closed bonding chamber, in an ambient of nitrogen or air at a background pressure ranging from 0.01 atm to 1 atm. For example, after wafers are brought into contact, a force ranging from approximately 0.1 MPa to 1 MPa may be applied. While this force is maintained, the contacted wafer pair, e.g., structure including the donor substrate 702 and the structure including the support substrate 5, may be brought to a peak temperature above the melting point of the composition for at least one of the bonding layers having reference numbers 710, 706a, 706b to effectuate the engagement of the structures and the formation of the bonding layer 711 that engages the stack including the supporting substrate 5 and the strain balancing layer (SBL) 10 to the stack including the semiconductor junction 15, as depicted in FIG. 2H.

In one example, in which the bonding layers 710 that are formed on the strain balancing layer (SBL) include a bilayer of the high melting point metal layer/low-melting-point metal layer, and it is desired to forming a bonding layer 711 including intermetallic compounds, the bonding layers may be brought to a peak temperature above the melting point of the low-melting-point metal for the low melting point bonding layers 706b.

In one example, the low temperature for bonding may range from 232° C. to 300° C. if the low-melting-point metal for the low melting point bonding layers 706b (and the low melting point bonding layer in the metal layers 710 on the strain balancing layer 10) is tin (Sn). This temperature may be maintained only briefly, e.g., for a time period ranging from 1 second to 60 seconds. In another example, the temperature may be maintained for a time ranging from 1 minute to 60 minutes. While the low-melting-point layers, e.g., the low melting point bonding layers 706b, (and low melting point layer within bonding layer 710) are in a liquid phase, they may conform to any non-planar topology at the bonded interface arising from (a) surface roughness of the donor or carrier wafer, (b) particles at the bonding interface, or (c) deliberate surface texturization of a rear solar cell surface, provided that such topology is thinner than the combined thickness of the low-melting-point metal layers on one or both of the donor and carrier wafer. Once the low melting point layers melt, diffusion between the low- and high-melting point metal layers, e.g., diffusion between the low melting point bonding layers 706b (and low melting layer within bonding layer 710) and the high melting point bonding layers 706a (and high melting layer within bonding layer 710) will typically be enhanced.

Referring to FIG. 2H, in some embodiments, the diffusion between the low melting point bonding layers 706b (and low melting point layer within bonding layer 710) and the high melting point bonding layers 706a (and high melting point layer within bonding layer 710), may lead to the formation of an intermetallic compound layer for the bonding layer identified by reference number 711. In some embodiments, the intermetallic compound layer can be comprised of Ni_{y}Sn_{z} (e.g. Ni₃Sn₄), or Ti_{w}Snₓ (e.g. Ti₆Sn₅), or CuᵤInᵥ (e.g. Cu₂In). The intermetallic compound layer may have a melting point substantially higher than the melting point of the low-melting-point metal layers 706b (and low melting point layer within bonding layer 710), and so the intermetallic compound layer may solidify isothermally even while the metal layer stack remains exposed to the peak bonding temperature. This approach to metallic bonding, where a resulting intermetallic metal compound bonding layer has a melting point higher than some of the constituent layers, has been referred to as Transient Liquid Phase bonding. Further details regarding some examples of Transient Liquid Phase bonding are described in “Transient Liquid Phase Bonding” by W. D. MacDonald and T. W. Eagar, Anna. Rev. Mater. Sci. 1992.22:23-46. This process may consume substantially all of the low melting point layers 706b and 710b, so the bonded metal joint will remain solid for temperatures well above the melting point of the low melting point metal. Some of high melting point layers 706a (and/or the high melting point layer within bonding layer 710) may remain unconsumed in the formation of intermetallic compound layer.

Referring to FIG. 21, the donor substrate 702 may be removed from the first portion of a solar cell bonded to the support substrate 5 by cleaving the donor substrate 702 within the porous layers 704a, 704b. Separation may be via mechanical force alone, or enhanced with various other methods. In one example, a wedged device (not shown) may be applied to induce separation at the exposed external edges of the porous regions 704a, 704b. In another example, separation at the porous layers 704a, 704b may be enhanced via application of a high pressure water jet directed at the edge of the porous layers 704a, 704b. Further details for one example of separation at the porous layers 704a, 704b that employs a high pressure water jet is described in Yonehara & Sakaguchi. In yet another example, a wet acid solution, such as HF/H₂O₂, may also be exposed to the porous layers 704 to them from the edge and enhance separation. It yet another example, the thermal stresses induced by the cool-down of the bonded donor substrate 702 and support substrate 5 may be enough to induce auto-separation, without the application of any force. It should be understood that the above examples of separation may be used individually or in various combinations.

Topside processing of the solar cell is now described with reference to FIGS. 2J-2Q. Referring to FIG. 2J, once the supporting substrate 5 and the attached solar cell layers (including the semiconductor junction 15), which includes the emitter region layer 717, the epitaxial semiconductor layer 714 (also referred to as base contact layer 714) and the base region layer 712, have been separated from the donor substrate 702, a residual of porous silicon layers 704b may remain on top of epitaxial semiconductor layer 714. FIGS. 2J-2Q are flipped vertically from previous diagrams. The residual porous silicon layers 704b may be removed with a wet acid etch as described in Yonehara & Sakaguchi, or in Nobuhiko Sato et al, Journal of the Electrochemical Society, v. 142 n.9 p. 3116-22; or via an etch in a KOH (Potassium hydroxide) solution; or via an ammonium fluoride (NH₄F) solution; or via polishing. In another example, residual porous Si layer 704b may be removed in a mixture of DI water, NH₄F and H₂O₂ in a ratio of e.g. 5:1:1, at a temperature of ranging from 40° C. to 90° C., for a time period ranging from 1 minute to 20 minutes. The etch process for removing the residual porous silicon layers 704b may be selective to the underlying epitaxial semiconductor layer 714. As used herein, the term “selective” in reference to a material removal process denotes that the rate of material removal for a first material is greater than the rate of removal for at least another material of the structure to which the material removal process is being applied. For example, the etch process for removing the residual porous layers 704b may etch all of the porous silicon (Si) of the residual porous layers 704b substantially faster than single-crystalline non-porous silicon of the epitaxial semiconductor layer 14. The transition of the surface appearance from non-specular to specular may provide indication that the porous silicon (Si) removal is substantially complete. In other embodiments, it may be advantageous to leave some or all of residual porous layers 704b intact, as the porous surface's roughness may enhance adhesion of the subsequently deposited grid metal.

In some embodiments, after splitting (also referred to as cleaving) the donor substrate 702 may be processed for reuse in the next wafer production cycle. This processing may include polishing, wet etching, or otherwise cleaning of the cleaved surface for subsequent formation of porous layers in future wafer production cycles. For example, this processing may include the removal of the portion of porous Si layers 704a, 704b which remained attached to the donor substrate 702, via immersion in a potassium hydroxide (KOH) solution of concentration 45% for a time period ranging from 30 minutes to 90 minutes at room temperature, e.g., 20° C. to 25° C.

Referring to FIG. 2K, a sacrificial patterned masking layer 750 with openings 751 can be formed for the subsequent electroplating of the solar cell top contact grid. This patterned masking layer can be formed by various methods. For example, photolithography can be used to pattern the sacrificial masking layer 750. In other examples, openings 751 in the sacrificial masking layer 750 may be formed using laser ablation and lift off processes. One example of a process that employs at least one of laser ablation and lift off processes to form openings 751 in the sacrificial masking layer 750 is described in “Laser ablation of etch resists for structuring and lift-off processes” by A.Knorz et al., Proc. 24th EU Photovolt. Spec.Conf, 2009, 2164-2167. In this approach, polymer masking layer 750 is deposited on a Si surface via screen printing. Openings 751 in the masking layer are then created via laser ablation using either UV or IR lasers as described in Knorz. As another alternative, the patterned masking layer 750 can be directly screen printed, with the openings 751 formed as part of the screen printing process.

In one example, the masking layer 750 can have a thickness ranging from approximately 0.5 microns to 20 microns, and the width of the openings 751 formed through the making layer 750 may range from 5 microns to 50 microns. In another example, the masking layer 750 can have a thickness ranging from approximately 1 micron to 5 microns, and the width of the openings 751 formed through the making layer 750 may range from 20 microns to 30 microns.

FIG. 2L depicts forming metal contactor lines 716 include portions within openings 751. The metal contactor lines 716 may be formed using physical vapor deposition (PVD) methods, such as sputtering; plating methods, such as electroplating and/or electroless plating; and chemical vapor deposition, such as metal organic chemical vapor deposition. In some embodiments, the metal contact lines 716 can be formed via Ni/Cu plating, as described for example in “Evolution of metal plating for silicon solar cell metallization” by A. Lennon et al., in Prog. Photovolt: Res. Appl. v21 n7 p1454-68 (2012). Plating may also be used to deposit an additional thin layer of Ag or Sn on top of the Cu, to protect the Cu lines from being oxidized, and promote easier soldering of tabs used for cell interconnection. This Ag or Sn can also protect the grid lines from the subsequent texturization etch. Plated line width is controlled by the width of openings 751, as masking layer 750 itself is not plated.

Referring to FIG. 2M, after plating masking layer 750 may be removed in a solvent solution. Alternately it may be removed as part of the subsequent surface texturization step.

After application of metal contact materials 716, the structure may be annealed at a temperature ranging from 100° C. to 400° C. This anneal may be performed in an ambient of e.g. forming gas.

Subsequently, referring to FIG. 2N, a texturized surface 715 can be formed to improve light trapping, for example in a potassium hydroxide (KOH) based solution, or a sodium hydroxide (NaOH) based solution. This texturization step may remove the base contact layer 714 in all exposed areas. Note that n-type region 714 is protected in the areas beneath the top grid 716. In some embodiments, the n-type region 714, which provides the base contact layer 714 only remains present between the metal contact materials 716 and the base region layer 712. The texturing step can remove the porous Si layer in all exposed areas, in embodiments where it was not removed in previous steps. The texturized surface 715 could be formed via a shallow texturization process to minimize the amount of silicon removal. An example shallow texturization process is described in Section 4.1.2.2 of “Development of a high performance ultra-thin silicon solar cell on steel substrate”, a Ph.D. thesis by Lu Wang (2014), UNSW Australia. In one example, the peak to valley depth of the textured surface may range from 100 nm to 5 microns. While the texturized surface is illustrated as fully regular, the texturized surface may also be partially or fully random. For example, for a surface with pyramidal texturing, the size of the pyramids may vary significantly.

Referring to FIG. 2O, passivation layer 730 can be deposited over the entire solar cell top surface. The passivation layer 730 can be a silicon nitride or silicon oxy-nitride layer, deposited for example by plasma enhanced chemical vapor deposition (PECVD). In other examples, the passivation layer 730 may be amorphous silicon (a-Si) or aluminum oxide (Al₂O₃). In addition to plasma-enhanced chemical vapor deposition (PECVD), the passivation layer 118 may also be deposited via methods such as atomic layer deposition (ALD), or thermal oxidation. The passivation layer 730 depicted in FIG. 2O can also serve as an anti-reflection coating.

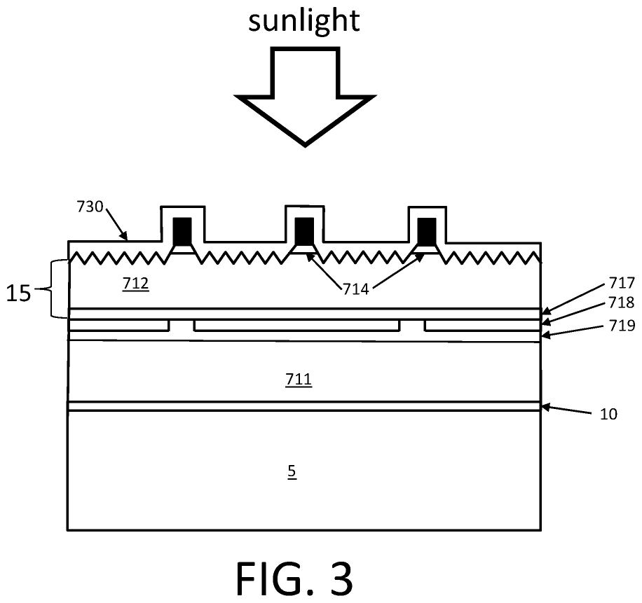

FIG. 3 illustrates one embodiment of the exemplary basic cell structure that can be provided by the method described in accordance with the process flow that is depicted in FIGS. 2A-2O. As depicted in FIG. 3, the solar cell includes a semiconductor junction 15 on a supporting substrate 5, in which a strain balancing layer 10 formed on the supporting substrate is positioned between the supporting substrate 5 and the semiconductor junction 15, wherein the strain balancing layer 10 counteracts forces that result from a differential in the coefficient of thermal expansion (CTE) between the supporting substrate 5 and the semiconductor junction layers 15. By counteracting the differential in the coefficient of thermal expansion (CTE) between the supporting substrate 5 and the semiconductor junction layer 15, the strain balancing layer 10 when integrated into the solar cell provides a solar cell that is resistant to warpage during processing, and remains substantially planar, as depicted in FIG. 3.

In one embodiment, the solar cell includes a supporting substrate 5 having a first thermal expansion coefficient, wherein the supporting substrate 5 has a composition of a steel based alloy, an iron nickel alloy or a combination thereof. A strain balancing layer 15 is present on a surface on the substrate 5. The strain balancing layer 15 has a second thermal expansion greater than the first thermal expansion coefficient. A solder bonding layer 711 is present on a surface of the strain balancing layer 10 to position the strain balancing layer 10 between the solder bonding layer 711 and the supporting substrate 5. In some embodiments, a solar cell stack including the semiconductor junction 15 has a bonded surface with the solder bonding layer 711 that is opposite the surface of the solder bonding layer 711 engaged to the strain balancing layer 10.

In some embodiments, the supporting substrate 5 can have a coefficient of thermal expansion of 15 ppm/° K. or less, and the supporting substrate 5 can a thickness ranging from 20 microns to 200 microns. In some embodiments, the strain balancing layer 10 has a coefficient of thermal expansion at least 50% greater than the coefficient of thermal expansion for the supporting substrate 5. For example, the strain balancing layer 10 has a metal with a composition selected from the group consisting of zinc (Zn), aluminum (Al), copper (Cu), indium (In), tin (Sn) and combinations thereof. In some embodiments, the strain balancing layer 10 has a thickness ranging from 5 microns to 20 microns. The semiconductor junction 15 may include N-type epitaxially grown silicon 712, which may provide the solar cell base region. The emitter region of the semiconductor junction 15 may be provided by the structure having reference number 717. An N+ epitaxially grown region 714 may provide the solar cell base contact region. Contact layer 719 may provide bottom electrical contact to the p-type emitter region 717. Contact layer 719 may provide light reflection for more complete light absorption in the base region. The contact layer identified by reference number 719 may be omitted.

The process sequence depicted in FIGS. 2A-2O, and the solar cell structure depicted in FIG. 2 are exemplary of only one embodiment of the present disclosure. It is not intended that the present disclosure be limited to this one example.

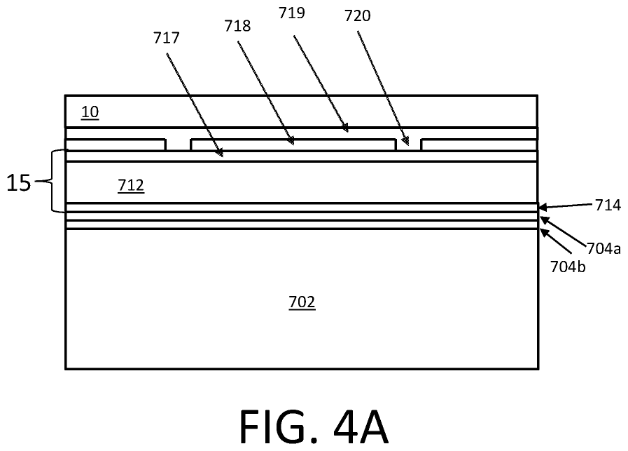

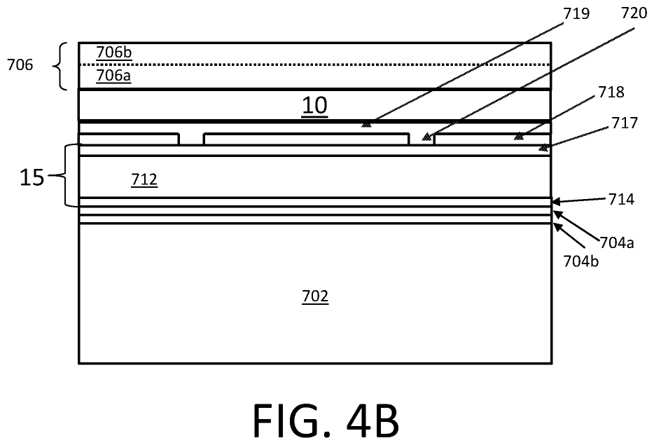

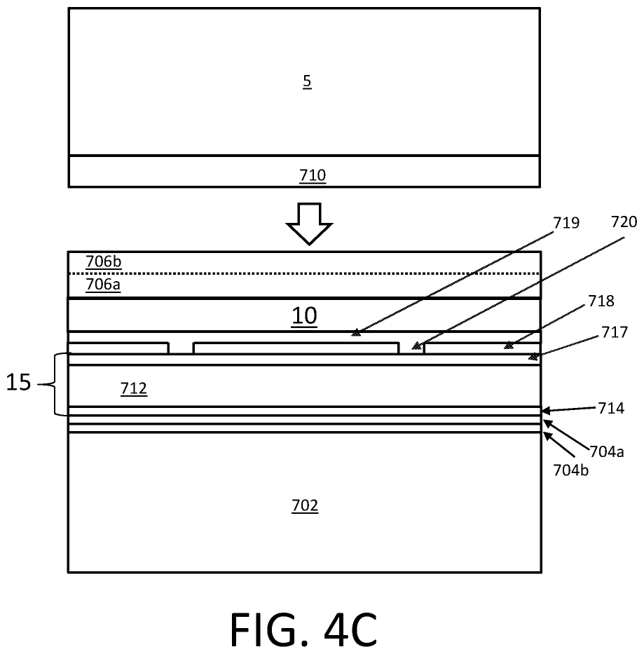

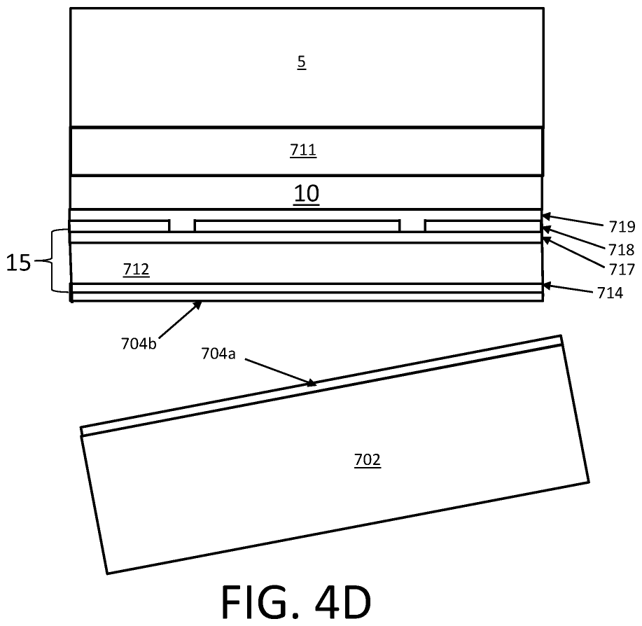

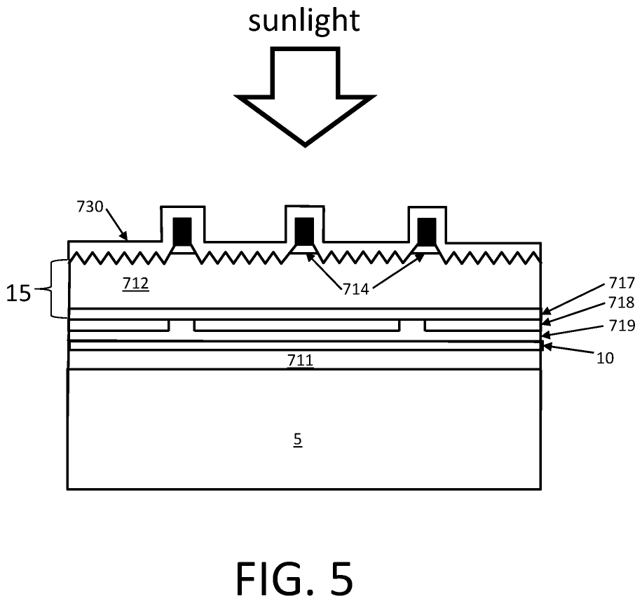

In another embodiment, the method includes forming the strain balancing layer 10 directly on the stack including the semiconductor junction 15 and the monocrystalline donor substrate 702, wherein the strain balancing layer 10 is present between the semiconductor junction 15 and solder bond layer 711. The solder bond layer 711 joins the stack of the strain balancing layer 10 and the semiconductor junction 15 to a supporting substrate 5. The process flow for this method sequence is depicted in FIGS. 4A-4D, and one embodiment of a final solar cell structure formed using the embodiment of the method sequence depicted in FIGS. 4A-4D is depicted in FIG. 5.

In this embodiment, the method of forming the solar cell device may also begin with forming a porous layer 704a, 704b in a monocrystalline donor substrate 702. This step has been described above with reference to FIG. 2A. In a following step, an epitaxial semiconductor layer 714 is formed on the porous layer 704a, 704b, and the semiconductor junction 15 for the solar cell structure is formed. The epitaxial semiconductor layer 714 is described with reference to FIG. 2B. FIG. 2B also depicts forming the semiconductor junction 15, which includes a base layer identified by reference number 712, and an emitter layer identified by reference number 717. The description for FIG. 2B is suitable for describing forming the semiconductor junction 15 in the present embodiment. Different from the embodiment having the process sequence depicted in FIGS. 2A-2O, the method in this embodiment may continue with forming the strain balancing layer (SBL) 10 directly to the stack including the semiconductor junction 15 and the monocrystalline donor substrate 702, which is depicted in FIG. 4A.

FIG. 4A illustrates the stack including the semiconductor junction 15, as well as back side processing to provide a passivation layer 718, contact layer 719, and openings 720 to the emitter layer 717. Each of these structures identified by reference numbers 718, 719 and 720 have been described above with reference to FIG. 2D. In the embodiment that is depicted in FIG. 4A, the strain balancing layer (SBL) 10 is formed on the contact layer 719 that is a layer of the stack including the semiconductor junction 15 and the monocrystalline donor substrate 702. The strain balancing layer (SBL) 10 that is depicted in FIG. 4A is similar to the strain balancing layer (SBL) identified by reference number 10 in FIG. 2E. The description for the strain balancing layer (SBL) 10 depicted in FIG. 2E is suitable for describing at least one example of the strain balancing layer (SBL) 10 that is depicted in FIG. 4A. For example, the strain balancing layer (SBL) 10 that is depicted in FIG. 4A may have a coefficient of thermal expansion (CTE) of at least 50% greater than the supporting substrate 5. In some embodiments, the strain balancing layer (SBL) 10 has a metal with a composition selected from the group consisting of zinc (Zn), aluminum (Al), copper (Cu), indium (In), tin (Sn) and combinations thereof. In some embodiments, the strain balancing layer (SBL) 10 can have a thickness ranging from 5 microns to 20 microns. The strain balancing layer (SBL) 10 can be formed using electroplating, physical vapor deposition (PVD), sputtering, evaporation, electroless deposition and combinations thereof. It is noted that the supporting substrate 5 has not yet been bonded to the structure depicted in FIG. 4A.

Referring to FIG. 4B, solder bonding layers 706 may then be formed on the strain balancing layer (SBL) 10, in which the strain balancing layer (SBL) 10 is present on a stack that includes the semiconductor junction 15 and the monocrystalline donor substrate 702. The solder bonding layer 706, 706a, 706b that is depicted in FIG. 4B has been described above with reference to FIG. 2F. The processing described in FIG. 2F for preparing the surface for bonding is equally applicable to the process sequence including FIG. 4B.

FIG. 4C illustrates bonding the supporting substrate 5 to the structure depicted in FIG. 4B through the bonding layers identified by reference numbers 706, 706a, 706b and 710. Similar to the embodiment having the process sequence depicted in FIGS. 2A-2O, the supporting substrate can be composed of a steel based alloy, an iron nickel alloy, or a combination thereof. The supporting substrate identified by reference number 5 in FIG. 4C is similar to the supporting substrate 5 that is described in FIG. 2E. Therefore, the description for the supporting substrate 5 that is depicted in FIG. 2E is suitable for at least one embodiment of the supporting substrate 5 depicted in FIG. 4C. For example, the supporting substrate 5 can coefficient of thermal expansion of 15 ppm/° K. or less, and the supporting substrate has a thickness ranging from 20 microns to 200 microns.

Engaging the strain balancing layer 10 that was formed on the stack including the semiconductor junction 15 for the solar cell structure to a supporting substrate 5 through the bonding layers 706, 706a, 706b, 710, as depicted in FIG. 4C, is similar to the bonding sequence described using the same reference numbers to identify bonding layers that are depicted in FIGS. 2F-2H. For example, the solder bonding layers 706, 706a, 706b, 710 comprises at least one of nickel (Ni) and tin (Sn).

FIG. 4D illustrates separating the semiconductor junction 15 from the monocrystalline donor substrate 702 across the porous layer 704a, 704b, wherein the strain balancing layer 10 counteracts a differential in the thermal coefficient of expansion between the semiconductor junction 15 and the supporting substrate 5 to counteract warpage of the stack of the semiconductor junction 15, bonding layer 706, 706a, 706b, 710 and the supporting substrate 5. Separating the monocrystalline substrate 702 across the porous layers 704a, 704b has been described above with reference to FIG. 2I.

The process sequence may continue with top side processing of the layered stack including the semiconductor junction 15 to provide the solar cell depicted in FIG. 5. One example of top side processing that is suitable for being applied to the structure depicted in FIG. 3D has been described above with reference to the sequence from FIG. 2J to FIG. 2O. Each of the reference numbers in FIG. 5 having matching reference numbers in the process sequence depicted in FIGS. 2J to 2O can be described by the description for those reference numbers that have been provided above when describing FIGS. 2J to 2O.

FIG. 5 depicts one embodiment of a solar cell that includes a supporting substrate 5 having a first thermal expansion coefficient, wherein the supporting substrate 5 has a composition of a steel based alloy, an iron nickel alloy, or a combination thereof; a solder bonding layer 711 on a surface of the surface of the supporting substrate 5; a strain balancing layer (SBL) 10 having a second thermal expansion greater than the first thermal expansion coefficient on a surface of the solder bonding layer 711 opposite the surface of the solder bonding layer (SBL) 10 that is in contact with the supporting substrate 5; and a semiconductor junction 15 engaged to the strain balancing layer (SBL) 10.

Embodiments have also been contemplated in which the bonding layers 706, 706a, 706b, 710, 711 employed in the layer transfer methods for forming solar cells have thicknesses selected to function as a strain balancing layer (SBL). It is noted that the figures supplied in FIGS. 1A-5 are suitable for describing this embodiment, so long as the strain balancing layer (SBL) 10 is omitted and the thickness of the bonding layers 706, 706a, 706b, 710, 711 is increased in order for the coefficient of thermal expansion of the bonding layers is significant enough to counteract the differential in the coefficient of thermal expansion between the supporting substrate 5 and the semiconductor junction 15. One example of a method that employs the bonding layers 706, 706a, 706b, 710, 711 of a strain balancing layer may begin with forming a porous layer 704a, 704b in a monocrystalline donor substrate 702; and forming an epitaxial semiconductor layer 714 on the porous layer. The method may continue with forming the junction 15 for the solar cell structure on the epitaxial semiconductor layer 714. The junction 15 may include a base layer 712, and an emitter layer 717.

The method may continue with engaging the semiconductor junction 15 for the solar cell structure to a supporting substrate 5 through a bonding layer 706, 706a, 706b, 710, 711. The supporting substrate 5 has a composition of a steel based alloy, an iron nickel alloy, or a combination thereof. In this embodiment, the composition and thickness of the bonding layer 706, 706a, 706b, 710, 711 is selected to provide a strain balancing layer. For example, the bonding layer 706, 706a, 706b, 710, 711 may be composed of tin (Sn). In this embodiment, the thickness of the bonding layer 706, 706a, 706b, 710, 711 may range from 10 microns to 20 microns.

The method may continue with separating the semiconductor junction 15 from the monocrystalline donor substrate 702 across the porous layer 704a, 704b, wherein the strain balancing layer provided by the bonding layer 706, 706a, 706b, 710, 711 counteracts a differential in the thermal coefficient of expansion between the semiconductor junction 15 and the supporting substrate 5 to counteract warpage.

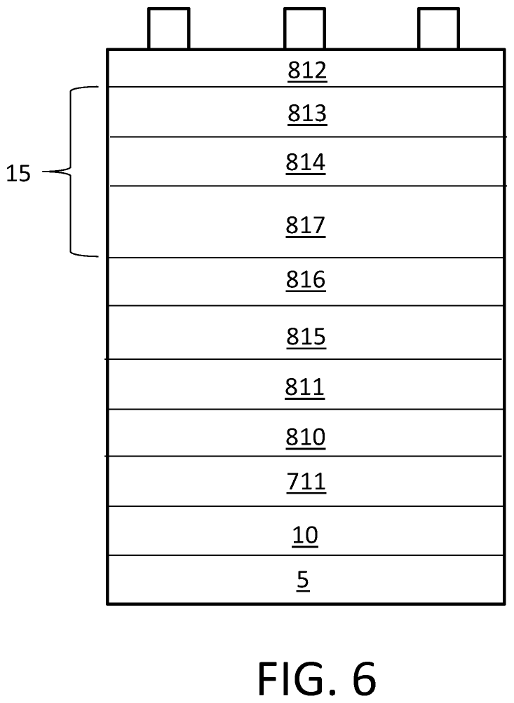

In yet other embodiments of the present disclosure, the strain balancing layer may be applicable to methods and structures that employ silicon heterojunction type devices similar to those depicted in FIG. 6, as opposed to passive emitter rear cell (PERC) type devices, similar to those that have been described above with reference to FIGS. 1A-5. In some embodiments of the silicon heterojunction type devices that are depicted in FIG. 6, the design can allow for bonding to a silicon wafer followed by a partial wet chemical etch back to provide the silicon layer thickness for the device. This can provide an alternative process flow than the layer splitting methodology that includes forming a porous silicon layer, epitaxially forming a semiconductor layer (such as silicon) atop the porous silicon layer, bonding to epitaxially formed layer with a supporting substrate, and splitting the porous silicon layer.

FIG. 6 illustrates one example of a silicon (Si) heterojunction solar cell that includes the strain balancing layer 10 that provides for a planar solar cell by countering warpage effects in the solar cell. The solar cell depicted in FIG. 6 may be a single heterojunction (SHJ) solar cell. The strain balancing layer 10 that is depicted in FIG. 6 is similar to the strain balancing layer 10 that has described above with reference to FIGS. 1A-5. Therefore, the above description of the strain balancing layer 10 from FIGS. 1A-5 is applicable for describing at least one embodiment of the strain balancing layer 10 that is depicted in FIG. 6. For example, the strain balancing layer 10 that is depicted in FIG. 6 may be composed of zinc (Zn). The thickness of the balancing layer 10 is typically selected to provide a thermal expansion that counteracts the differences in thermal expansion of the supporting substrate 5 and the junction 15.

The supporting substrate 5 that is depicted in FIG. 6 is similar to the supporting substrate 5 that is described in FIGS. 1A-5. Therefore, the above description for the supporting substrate 5 with reference to FIGS. 1A-5 is applicable for providing the description of at least one embodiment of a supporting substrate 5 for the structure depicted in FIG. 6. For example, the above description of FIG. 2E describes forming a strain balancing layer 10 on a supporting substrate 5. The description of the supporting substrate 5, as well as the strain balancing layer 10, from FIG. 2E provide at least one embodiment of those structures having same reference numbers in FIG. 6.

In some embodiments, the junction 15 includes a p-type doped silicon emitter layer and an n-type doped silicon base layer that are separated by an intrinsic semiconductor layer in a PIN arrangement. The n-type doped silicon base layer may be a crystalline silicon (c-Si) layer 817 having a monocrystalline crystal structure.

In some embodiments, the crystalline silicon (c-Si) layer may have a thickness ranging from 5 microns to 50 microns. In one example, the crystalline silicon (c-Si) layer has a thickness ranging from 10 microns to 40 microns. The thickness of the crystalline silicon (c-Si) layer 817 may be controlled by an etch back of a monocrystalline Si wafer, until the appropriate thickness is achieved. The etch back process may be applied following joining of the material layer for the crystalline silicon (c-Si) layer 817 to the strain balancing layer 10 through a bonding layer 711. For example, a wafer of the material for providing the crystalline silicon (c-Si) layer 817 may be bonded to a supporting substrate 5 through the bonding layer 711 and the strain balancing layer 10, wherein following bonded engagement the wafer is thinned using a subtractive etch process to provide the selected thickness for the crystalline silicon (c-Si) layer 817. This etch back can be for example using a solution of potassium hydroxide in deionized (DI) water at a temperature that in some examples may range from 70° C. to 100° C. The solution may include in the range of 20-50% KOH, with the remainder being DI water. The strain balancing layer 10 is present on the supporting substrate 5. The strain balancing layer 10 may be present between the junction 15 and the bonding layer 711. The strain balancing layer 10 may be present between the bonding layer 711 and a supporting substrate 5, as shown in FIG. 6. The bonding layer 711 that is depicted in FIG. 6 is similar to the bonding layer 711 described with reference to FIGS. 2H-3. Therefore, the description of the bonding layer 711 that is provided in FIGS. 2H-3 is suitable for describing at least one embodiment of the bonding layer 711 depicted in FIG. 6.

In some embodiments, the p-type doped silicon emitter layer 813 of the junction 15 may have an amorphous crystalline structure. In one example, this amorphous silicon (α-Si) layer 813 maybe composed of amorphous hydrogenated silicon (α-Si:H). The amorphous silicon (α-Si) layer 813 may have a thickness of 20 nm or less. In one example, the amorphous silicon (α-Si) layer 813 has a thickness ranging from 1 nm to 10 nm. In another example, the amorphous silicon (α-Si) layer 813 has a thickness ranging from 1 nm to 5 nm. The amorphous silicon (α-Si) layer 813 functions as the emitter, when the crystalline silicon (c-Si) layer has an opposite conductivity type, e.g., when the amorphous (α-Si) layer 813 has a p-type conductivity and the crystalline silicon (c-Si) layer 917 has an n-type conductivity type.

The intrinsic semiconductor layer of the junction 15 may be an intrinsic amorphous silicon (α-Si(i)) layer 814, with an amorphous crystalline structure. In one example, the intrinsic amorphous silicon (α-Si(i)) layer 814 may be composed of amorphous hydrogenated silicon (α-Si:H(i)). The thickness of the intrinsic amorphous silicon (α-Si(i)) layer 814 may be 10 nm or less. In one example, the thickness of the intrinsic amorphous silicon (α-Si(i)) layer 814 may range from 1 nm to 5 nm. In some embodiments, charge carriers are produced in the crystalline silicon (c-Si) layer 817 via absorption of light, wherein the electric field is provided by the opposing conductivity emitter and base in the operation of the solar cell.

Each of the intrinsic amorphous silicon (α-Si(i)) layer 814 and the amorphous silicon (α-Si) layer 813 may be formed using deposition process steps, for example by plasma-enhanced chemical vapor deposition (PECVD) using deposition temperatures for example in the range of 150-300C.

Still referring to FIG. 6, the solar cell may further include a transparent conductive oxide (TCO) layer 812 atop the junction 15. The transparent conductive oxide (TCO) layer 812 may be composed of indium tin oxide (ITO), aluminum zinc oxide (AZO) or a combination thereof. In some embodiments, the thickness of this TCO layer 812 may range from 50 nm to 100 nm. In one example, the thickness of the TCO layer 812 is equal to 80 nm, and the TCO layer 812 can function as an anti-reflective coating (ARC). The TCO layer can be formed e.g. by sputtering or evaporation. In some embodiments, electrodes composed of a metal, such as silver (Ag) may be formed atop the TCO layer 812. In some embodiments, the electrode may be formed e.g. by screen printing and comprised of silver (Ag). It is noted that screen printing is only one embodiment for the methods of forming the silver electrodes. For example, in some other embodiments, the electrodes could be formed via electroplating, for example of Cu, or a stack of Ni/Cu, Ni/Cu/Sn, or Ni/Cu/Ag.

In some embodiments, a stack of material layers may be present between the junction 15 and the bonding layer 711. For example, a passivation layer 816 of intrinsic amorphous silicon (α-Si(i)) may be present underlying the crystalline silicon (c-Si) layer 817. In one example, this layer 816 maybe composed of intrinsic amorphous hydrogenated silicon (α-Si:H(i)). The thickness of the passivation layer 816 may be on the order of 5 nm. The stack of material layers present between the junction 15 and the bonding layer 711 may also include an n-type doped amorphous silicon layer (α-Si) layer 815, which can have a thickness on the order of 10 nm. The n-type doped amorphous silicon layer (αa-Si) layer 815 may be present underlying the passivation layer. The amorphous Si layers 815 and 816 may be deposited for example by plasma-enhanced chemical vapor deposition (PECVD) using deposition temperatures for example in the range of 150-300C. The stack of material layer present between the junction 15 and the bonding layer 711 may also include a transparent conductive oxide (TCO) layer 811, which may be present underlying amorphous Si layer 815. The transparent conductive oxide (TCO) layer 811 may be composed of indium tin oxide (ITO), aluminum zinc oxide (AZO) or a combination thereof. In some embodiments, the thickness of this TCO layer 811 may range from 50 nm to 100 nm. The stack of material layer present between the junction 15 and the bonding layer 711 may also include a metal layer 810, which may be present underlying TCO layer 811. The metal layer 810 may be composed of silver (Ag) or aluminum (Al). In some embodiments, the thickness of this metal layer 810 may range from 100 nm to 1000 nm. The TCO layer 811 and the metal layer 810 may be deposited e.g. by sputtering.

In some embodiments, the solar cell that is depicted in FIG. 6 may be formed using a method that includes forming a strain balancing layer 10 on a supporting substrate 5, the supporting substrate 5 having a composition of a steel based alloy, an iron nickel alloy, or a combination thereof; and joining a crystalline semiconductor wafer to the supporting substrate 5 and the strain balancing layer 10 to a layered stack including a semiconductor junction 15 through a bonding layer 711. It is noted that the bilayer of the high melting point metal layer/low-melting-point metal layer may be helpful for forming intermetallic compound layer in the bonding layer 711 (as depicted in FIG. 2H) that engages the stack including the supporting substrate 5 and the strain balancing layer 10 to the stack including the semiconductor junction 15. However, any bonding composition that has been described herein may be employed in the bonding layer 711, and it is not necessary that the bonding composition form an intermetallic compound layer. The method may further include thinning the crystalline semiconductor wafer with an etch back process; and forming a semiconductor junction with a crystalline semiconductor layer 817 provided by the crystalline semiconductor wafer after the etch back process. The strain balancing layer 10 counteracts a differential in the thermal coefficient of expansion between the semiconductor junction 15 and the supporting substrate 5 to counteract warpage of the stack of the semiconductor junction 15, the bonding layer 711 and the supporting substrate 5.

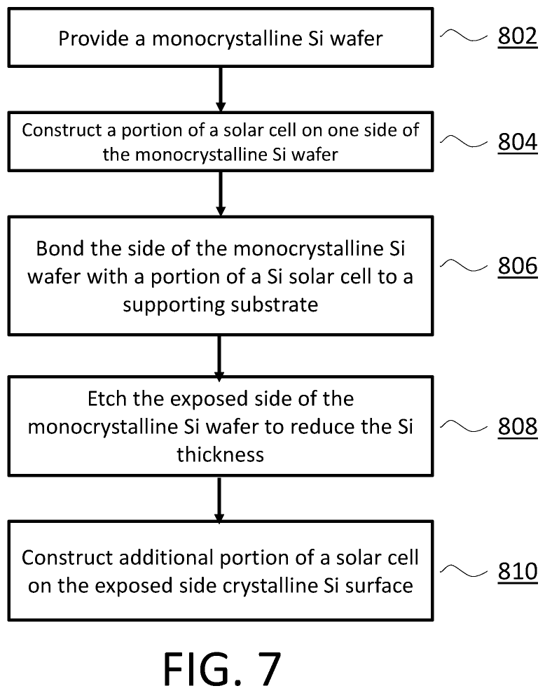

In some embodiments, the solar cell that is depicted in FIG. 6 may be formed using a method summarized in FIG. 7. A crystalline semiconductor wafer is provided (block 802). A solar cell or device is constructed or partially constructed on one side of the crystalline semiconductor wafer (block 804). The side of the crystalline semiconductor wafer with the partially constructed solar cell or device is bonded to a supporting substrate 5 through a bonding layer 711 and strain balancing layer 10 (block 806). The exposed (i.e. non-bonded) side of the monocrystalline Si wafer is thinned using a subtractive etch process, where the remaining portion is crystalline silicon (c-Si) layer 817 (block 808). An additional portion of a solar cell or device is constructed on the exposed surface of crystalline silicon (c-Si) layer 817 (block 810).

It should be noted that the solar cell structure is for illustrative purposes and the invention is not limited to the disclosed structure. Various devices may be constructed, and materials can be deposited by a variety of techniques, including thermal or e-beam evaporation, DC or RF sputtering, electroplating, molecular beam epitaxy (MBE), atomic layer deposition (ALD), pulsed-laser deposition (PLD), spin coating, MOCVD, HVPE, liquid phase epitaxy (LPE), screen printing, or any other suitable technique. Materials can be annealed or undergo chemical reactions following deposition, or after additional materials or reactants are deposited or placed in proximity.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of this invention are presented for purposes of illustration and description. They are not intended to be exhaustive or to limit the invention to the precise forms disclosed; obviously many modifications and variations are possible in view of the above teachings. The embodiments were chosen and described in order to best explain the principles of the invention and its practical applications. These procedures will enable others, skilled in the art, to best utilize the invention and various embodiments with various modifications. It is intended that the scope of the invention be defined by the following claims and their equivalents. Modifications and substitutions by one of ordinary skill in the art are considered to be within the scope of the present invention, which is not to be limited except by the following claims.

What is claimed is:

1. A method of forming a solar cell device comprising:
forming a porous layer in a monocrystalline donor substrate;
forming an epitaxial semiconductor layer on the porous layer;
forming a semiconductor junction for the solar cell structure on the epitaxial semiconductor layer;
forming a strain balancing layer on a supporting substrate, the supporting substrate having a composition of a steel based alloy, an iron nickel alloy, or a combination thereof;
joining a layered stack of the supporting substrate and the strain balancing layer to a layered stack including a semiconductor junction through a bonding layer; and
separating the semiconductor junction from the monocrystalline donor substrate across the porous layer, wherein the strain balancing layer counteracts a differential in the thermal coefficient of expansion between the semiconductor junction and the supporting substrate to counteract warpage of the stack of the semiconductor junction, the bonding layer and the supporting substrate.

2. The method of claim 1, wherein the strain balancing layer has a coefficient of thermal expansion at least 50% greater than the supporting substrate.

3. The method of claim 1, wherein the supporting substrate has coefficient of thermal expansion of 15 ppm/° K. or less.

4. The method of claim 1, wherein the strain balancing layer has a metal with a composition selected from the group consisting of zinc (Zn), aluminum (Al), copper (Cu), indium (In), tin (Sn) and combinations thereof.

5. The method of claim 3, wherein the supporting substrate has a thickness ranging from 20 microns to 200 microns.

6. The method of claim 1, wherein the strain balancing layer has a thickness ranging from 5 microns to 20 microns.

7. A solar cell comprising:
a supporting substrate having a first thermal expansion coefficient, wherein the supporting substrate has a composition of a steel based alloy, an iron nickel alloy or a combination thereof;
a strain balancing layer surface on the substrate, the strain balancing layer having a second thermal expansion greater than the first thermal expansion coefficient;
a solder bonding layer on a surface of the strain balancing layer to position the strain balancing layer between the solder bonding layer and the substrate of the steel alloy; and
a layered stack including semiconductor junction having a bonded surface to the solder bonding layer that is opposite the surface of the solder bonding layer engaged to the strain balancing layer.

8. The solar cell of claim 7, wherein the strain balancing layer has a coefficient of thermal expansion at least 50% greater than the supporting substrate.

9. The solar cell of claim 7, wherein the supporting substrate has coefficient of thermal expansion of 15 ppm/° K. or less.

10. The solar cell of claim 7, wherein the supporting substrate is composed of stainless steel.

11. The solar cell of claim 7, wherein the supporting substrate has a thickness ranging from 20 microns to 200 microns.

12. The solar cell of claim 7, wherein the strain balancing layer has a metal with a composition selected from the group consisting of zinc (Zn), aluminum (Al), copper (Cu), indium (In), tin (Sn) and combinations thereof.

13. The solar cell of claim 7, wherein the strain balancing layer has a thickness ranging from 5 microns to 20 microns.

14. A solar cell comprising:
a supporting substrate having a first thermal expansion coefficient, wherein the supporting substrate has a composition of a steel based alloy, an iron nickel alloy, or a combination thereof;
a solder bonding layer on a surface of the surface of the substrate;
a strain balancing layer having a second thermal expansion greater than the first thermal expansion coefficient on a surface of the solder bonding layer opposite the surface of the solder bonding layer that is in contact with the supporting substrate; and
a semiconductor junction engaged to the strain balancing layer.

15. The solar cell of claim 14, wherein the strain balancing layer has a coefficient of thermal expansion at least 50% greater than the supporting substrate.

16. The solar cell of claim 14, wherein the supporting substrate has coefficient of thermal expansion of 15 ppm/° K. or less.

17. The solar cell of claim 14, wherein the supporting substrate is composed of stainless steel.

18. The solar cell of claim 14, wherein the supporting substrate has a thickness ranging from 20 microns to 200 microns.

19. The solar cell of claim 14, wherein the strain balancing layer has a metal with a composition selected from the group consisting of zinc (Zn), aluminum (Al), copper (Cu), indium (In), tin (Sn) and combinations thereof.

20. The solar cell of claim 14, wherein the strain balancing layer has a thickness ranging from 5 microns to 20 microns.
